(19) United States
(12) Patent Application Publication
(10) Pub. No.: US 2017/0088672 A1
(43) Pub. Date: Mar. 30, 2017

(54) POLYMER, PHOTOSENSITIVE RESIN COMPOSITION, AND ELECTRONIC DEVICE

(71) Applicant: SUMITOMO BAKELITE CO., LTD., Tokyo (JP)

(72) Inventors: Osamu Onishi, Tokyo (JP); Haruo Ikeda, Tokyo (JP)

(73) Assignee: SUMITOMO BAKELITE CO., LTD., Tokyo (JP)

(21) Appl. No.: 15/126,854

(22) PCT Filed: Mar. 10, 2015
(86) PCT No.: PCT/JP2015/057031

§ 371 Date: Sep. 16, 2016

(30) Foreign Application Priority Data
Mar. 20, 2014 (JP) 2014-058132

(51) Int. Cl. C08G 73/10; G03F 7/075; G03F 7/039; C08G 77/04

(52) U.S. Cl. CPC C08G 73/10; C08G 77/04; G03F 7/0758; G03F 7/039

(57) ABSTRACT

Provided is a polymer including a structural unit represented by the following Formula (1a); and a structural unit represented by the following Formula (1b).

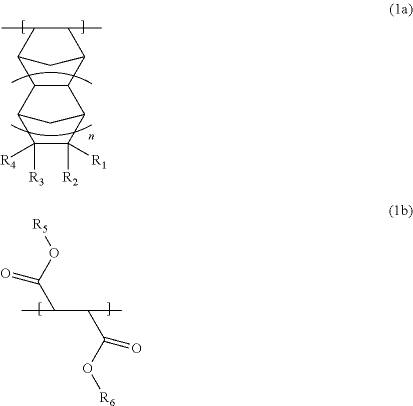

(In Formula (1a), n represents 0, 1, or 2. R₁, R₂, R₃, and R₄ each independently represent hydrogen or an organic group having 1 to 10 carbon atoms, at least one of R₁, R₂, R₃, and R₄ representing an organic group including a carboxyl group, an epoxy ring, or an oxetane ring. In Formula (1b), R₅ and R₆ each independently represent an alkyl group having 1 to 10 carbon atoms.)

### TECHNICAL FIELD

The present invention relates to a polymer, a photosensitive resin composition, and an electronic device.

### BACKGROUND ART

A resin film obtained by exposing a photosensitive resin composition is occasionally used as an insulating film constituting an electronic device. As techniques related to such a photosensitive resin composition, those described in Patent Documents 1 and 2 may be exemplified. Patent Document 1 describes a positive type photosensitive resin composition that includes an alkali-soluble resin, a 1,2-quinonediazide compound, and a crosslinkable compound having two or more epoxy groups. Patent Document 2 describes a radiation-sensitive resin composition containing a copolymer which includes a polymerization unit of unsaturated carboxylic acid and a polymerization unit of a specific compound, a 1,2-quinonediazide compound, and a latent acid-generating agent.

### RELATED DOCUMENT

### Patent Document

[Patent Document 1] Japanese Laid-open Patent Application Publication No. 2004-271767

[Patent Document 2] Japanese Laid-open Patent Application Publication No. H9(1997)-230596

### SUMMARY OF THE INVENTION

As a base polymer of a photosensitive resin composition for forming an interlayer insulating film, for example, an acrylic polymer has been used as described in Patent Document 2. The present inventors examined the use of an alicyclic olefin-based polymer having more excellent heat resistance, insulating properties, and low water adsorption as a base polymer. However, when the alicyclic olefin-based polymer is particularly used for a thick film or when developing the film with a highly-concentrated developer, there is a concern that cracks may occur by strain in a coating film assumed to be caused by the rigidity or hydrophobicity derived from an alicyclic hydrocarbon skeleton. Under such circumstances, there is a strong demand for development of a photosensitive resin composition having excellent crack resistance and properties required of a cured film such as an interlayer insulating film.

According to the present invention, there is provided a polymer including: a structural unit represented by the following Formula (1a); and a structural unit represented by the following Formula (1b).

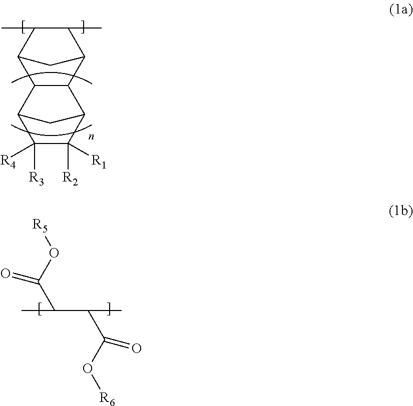

In Formula (1a), n represents 0, 1, or 2. R₁, R₂, R₃, and R₄ each independently represent hydrogen or an organic group having 1 to 10 carbon atoms, at least one of R₁, R₂, R₃, and R₄ representing an organic group including a carboxyl group, an epoxy ring, or an oxetane ring. In Formula (1b), R₅ and R₆ each independently represent an alkyl group having 1 to 10 carbon atoms.

Further, according to the present invention, there is provided a photosensitive resin composition which is used for forming a permanent film, including the above-described polymer.

Furthermore, according to the present invention, there is provided an electronic device including a permanent film formed from the above-described photosensitive resin composition.

According to the present invention, it is possible to suppress the occurrence of cracks in a patterning process.

### BRIEF DESCRIPTION OF THE DRAWINGS

The above-described and other objects, features, and advantages will become more apparent with reference to preferred embodiments described below and the accompanying drawing.

FIG. 1 is a sectional view showing an example of an electronic device.

### DESCRIPTION OF EMBODIMENTS

Hereinafter, embodiments will be described with reference to the accompanying drawing. In addition, in the drawing, the same constituent elements are denoted by the same reference numerals and the description thereof will not be repeated.

A polymer (first polymer) according to the present embodiment includes a structural unit represented by the following Formula (1a) and a structural unit represented by the following Formula (1b).

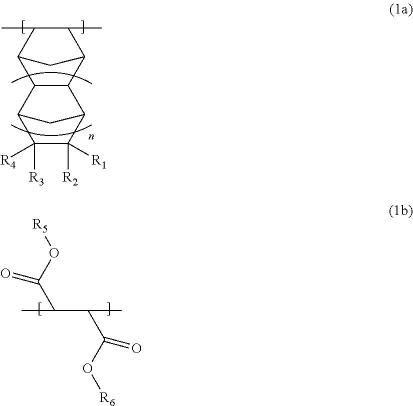

In Formula (1a), n represents 0, 1, or 2. R₁, R₂, R₃, and R₄ each independently represent hydrogen or an organic group having 1 to 10 carbon atoms, at least one of R₁, R₂, R₃ and R₄ representing an organic group including a carboxyl group, an epoxy ring, or an oxetane ring. In Formula (1b), R₅ and R₆ each independently represent an alkyl group having 1 to 10 carbon atoms.

The present inventors conducted intensive research on a new polymer capable of suppressing the occurrence of cracks in a patterning process applied to a photosensitive resin film, that is, a polymer capable of achieving a photosensitive resin composition with excellent crack resistance. As a result, the present inventors have newly developed a first polymer having a structural unit represented by the above-described Formula (1a) and a structural unit represented by the above-described Formula (1b). When such a first polymer is used, it is possible to provide moderate elasticity for a coating film so that the occurrence of cracks in a development process can be suppressed. Therefore, according to the present embodiment, it is possible to suppress the occurrence of cracks in the patterning process.

In addition, according to the present embodiment, it is possible to satisfy various properties required of a permanent film such as an interlayer insulating film while improving crack resistance as described above. Examples of such properties include heat resistance, transparency, liquid chemical resistance, and a low dielectric constant. Further, it is possible to contribute to improvement in developability, resolution, and adhesion.

Hereinafter, the first polymer, the photosensitive resin composition, and the electronic device will be described in detail.

(First Polymer)

First, the first polymer will be described.

As described above, the first polymer according to the present embodiment is configured of a copolymer having a structural unit represented by the following Formula (1a) and a structural unit represented by the following Formula (1b).

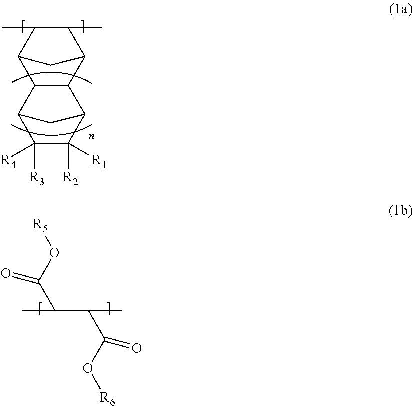

In Formula (1a), n represents 0, 1, or 2. R₁, R₂, R₃, and R₄ each independently represent hydrogen or an organic group having 1 to 10 carbon atoms, at least one of R₁, R₂, R₃, and R₄ representing an organic group including a carboxyl group, an epoxy ring, or an oxetane ring. In Formula (1b), R₅ and R₆ each independently represent an alkyl group having 1 to 10 carbon atoms.

As described above, the first polymer according to the present embodiment includes a structural unit derived from norbornene having an organic group that includes a carboxyl group, an epoxy ring, or an oxetane ring; and a structural unit having an alkoxycarbonyl group bonded to the main chain. The present inventors have found that crack resistance of a resin film formed from a photosensitive resin composition including the first polymer can be improved in a case where the first polymer includes both of these structural units. It is assumed that improvement in crack resistance is due to improved balance among properties such as sensitivity, curability, and elasticity of the resin film formed from the photosensitive resin composition. Consequently, according to the present embodiment, it is possible to suppress the occurrence of cracks in the patterning process.

Moreover, according to the first polymer of the present embodiment, properties required of the photosensitive resin composition used to form a permanent film, such as liquid chemical resistance, reworkability, transparency, and the low dielectric constant in addition to crack resistance can be improved.

In a case where a plurality of structural units represented by the above-described Formula (1a) are present in the first polymer, the structure of each of the structural units represented by the above-described Formula (1a) can be independently determined. Further, in a case where a plurality of structural units represented by the above-described Formula (1b) are present in the first polymer, the structure of each of the structural units represented by the above-described Formula (1b) can be independently determined.

Moreover, the molar ratio of a structural unit represented by Formula (1a) in the first polymer is not particularly limited, but is preferably equal to or greater than 1 and equal to or less than 90 based on 100 of the total first polymer. Further, the molar ratio of the structural unit represented by Formula (1b) in the first polymer is not particularly limited, but is preferably equal to or greater than 1 and equal to or less than 50 based on 100 of the total first polymer.

In the above-described Formula (1a), at least one of R₁, R₂, R₃, and R₄ represents a C1-C10 organic group which has a carboxyl group, an epoxy ring, or an oxetane ring. In the present embodiment, from the viewpoint of improving balance among reworkability, temporal stability, and solvent resistance, it is particularly preferable that any one of R₁, R₂, R₃, and R₄ represents a C1-C10 organic group which has a carboxyl group, an epoxy ring, or an oxetane ring, and the rest represents hydrogen.

From the viewpoint of improving transparency, it is particularly preferable that the first polymer includes two or more kinds selected from: a structural unit represented by the above-described Formula (1a) in which at least one of R₁, R₂, R₃, and R₄ represents an organic group having a carboxyl group; a structural unit represented by the above-described Formula (1a) in which at least one of R₁, R₂, R₃, and R₄ represents an organic group having an epoxy ring; and a structural unit represented by the above-described Formula (1a) in which at least one of R₁, R₂, R₃, and R₄ represents an organic group having an oxetane ring. Accordingly, it is possible to contribute to transparency of the resin film while improving balance among reworkability, temporal stability, and solvent resistance.

As the C1-C10 organic group constituting R₁, R₂, R₃, and R₄ and having a carboxyl group, an organic group represented by the following Formula (5) may be exemplified.

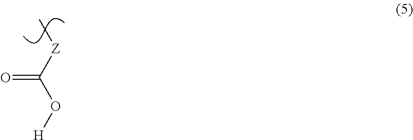

In the above-described Formula (5), Z represents a single bond or a divalent organic group having 1 to 9 carbon atoms. The divalent organic group constituting Z represents a linear or branched divalent hydrocarbon group which may include any one or two or more kinds selected from oxygen, nitrogen, and silicon. In the present embodiment, Z may represent, for example, a single bond or an alkylene group having 1 to 9 carbon atoms. Further, one or more hydrogen atoms in the organic group constituting Z may be substituted with a halogen atom such as fluorine, chlorine, bromine, or iodine. Examples of the organic group represented by the above-described Formula (5) include those represented by the following Formula (6).

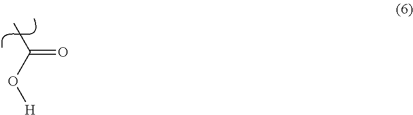

Examples of the C1-C10 organic group constituting R₁, R₂, R₃, and R₄ and having an epoxy ring include an organic group represented by the following Formula (3) and an organic group represented by the following Formula (7)

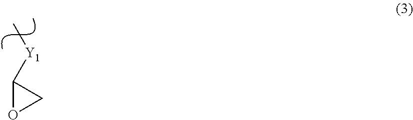

In Formula (3) Y₁ represents a divalent organic group having 4 to 8 carbon atoms. When a structural unit having such an organic group and represented by Formula (1a) is included, it is possible to more effectively improve crack resistance of a resin film formed from the photosensitive resin composition including the first polymer. The divalent organic group constituting Y₁ represents a linear or branched divalent hydrocarbon group which may include any one or two or more kinds selected from oxygen, nitrogen, and silicon. In the present embodiment, Y₁ may represent, for example, a linear or branched alkylene group having 4 to 8 carbon atoms. From the viewpoint of improving the crack resistance, it is more preferable to employ a linear alkylene group as Y₁. One or more hydrogen atoms in the organic group constituting Y₁ may be substituted with a halogen atom such as fluorine, chlorine, bromine, or iodine. Examples of the organic group represented by the above-described Formula (3) include those represented by the following Formula (3a).

Moreover, in the present embodiment, for example, a polymer may be employed as the first polymer, in which the polymer includes a plurality of structural units represented by the above-described Formula (1a), at least one of R₁, R₂, R₃, and R₄ representing an organic group represented by the above-described Formula (3) in at least some structural units represented by the above-described Formula (1a).

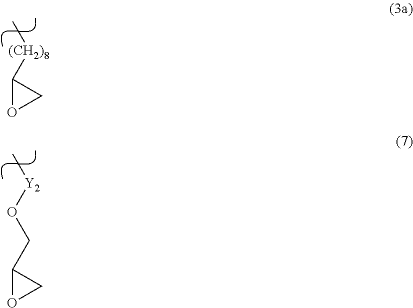

In the above-described Formula (7)_{f} Y₂ represents a single bond or a divalent organic group having 1 or 2 carbon atoms. The divalent organic group constituting Y represents a divalent hydrocarbon group which may include any one or two or more kinds selected from oxygen, nitrogen, and silicon. In the present embodiment, Y₂ may represent, for example, an alkylene group having 1 or 2 carbon atoms. Further, one or more hydrogen atoms in the organic group constituting Y₂ may be substituted with a halogen atom such as fluorine, chlorine, bromine, or iodine. Examples of the organic group represented by the above-described Formula (7) include those represented by the following Formula (7a).

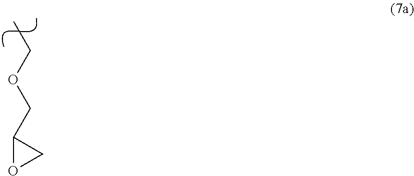

Examples of the C1-C10 organic group constituting R₁, R₂, R₃, and R₄ and having an oxetane ring include organic groups represented by the following Formula (8)

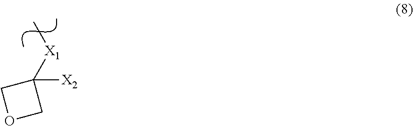

In Formula (8), X₁ represents a single bond or a divalent organic group having 1 to 7 carbon atoms and X₂ represents hydrogen or an alkyl group having 1 to 7 carbon atoms. A divalent organic group constituting X₁ is a linear or branched divalent hydrocarbon group which may have one or two or more kinds selected from oxygen, nitrogen, and silicon. Among these, a group including one or more linking groups such as an amino group (—NR—), an amide bond (—NHC(═O)—), an ester bond (—C(═O)—O—), a carbonyl group (—C(═O)—), and an ether bond (—O—) in the main chain is more preferable and a group including one or more linking groups such as an ester bond, a carbonyl group, and an ether bond in the main chain is particularly preferable. Further, one or more hydrogen atoms contained in the organic group constituting X₁ may be substituted with a halogen atom such as fluorine, chlorine, bromine, or iodine. Moreover, examples of the alkyl group constituting X₂ include a methyl group, an ethyl group, an n-propyl group, an isopropyl group, an n-butyl group, an isobutyl group, a sec-butyl group, a tert-butyl group, a pentyl group, a neopentyl group, a hexyl group, and a heptyl group. In addition, one or more hydrogen atoms contained in the alkyl group constituting X₂ may be substituted with a halogen atom such as fluorine, chlorine, bromine, or iodine. Examples of the organic group represented by the above-described Formula (8) include those represented by the following Formula (8a) and those represented by the following Formula (8b)

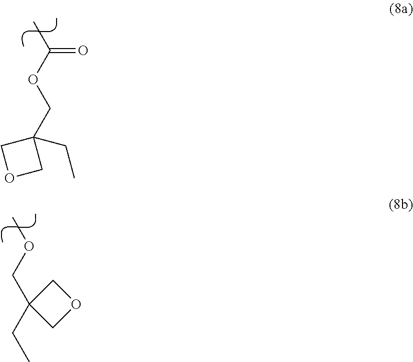

Examples of an organic group which constitutes R₁, R₂, R₃, and R₄ with 1 to 10 carbon atoms and none of a carboxyl group, an epoxy ring, and an oxetane ring include an alkyl group, an alkenyl group, an alkynyl group, an alkylidene group, an aryl group, an aralkyl group, an alkaryl group, a cycloalkyl group, and a heterocyclic group other than an epoxy group and an oxetane group. Examples of the alkyl group include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group. Examples of the alkenyl group include an allyl group, a pentenyl group, and a vinyl group. Examples of the alkynyl group include an ethynyl group. Examples of the alkylidene group include a methylidene group and an ethylidene group. Examples of the aryl group include a phenyl group and a naphthyl group. Examples of the aralkyl group include a benzyl group and a phenethyl group. Examples of the alkaryl group include a tolyl group and a xylyl group. Examples of the cycloalkyl group include an adamantyl group, a cyclopentyl group, a cyclohexyl group, and a cyclooctyl group. Further, in the alkyl group, the alkenyl group, the alkynyl group, the alkylidene group, the aryl group, the aralkyl group, the alkaryl group, the cycloalkyl group, and the heterocyclic group, one or more hydrogen atoms may be substituted with a halogen atom such as fluorine, chlorine, bromine, or iodine.

In the above-described Formula (1b), R₅ and R₆ each independently represent an alkyl group having 1 to 10 carbon atoms. Examples of the alkyl group include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group. Among these, from the viewpoint of improving the crack resistance, it is preferable that R₅ and R₆ each independently represent an alkyl group having 3 to 10 carbon atoms and particularly preferable that R₅ and R₆ each independently represent an alkyl group having 4 to 10 carbon atoms. Further, from the viewpoint of improving the crack resistance, it is more preferable that R₅ and R₆ which are present in one structural unit are the same as each other. Moreover, examples of the structural unit represented by the above-described Formula (1b) include those represented by the following Formula (9).

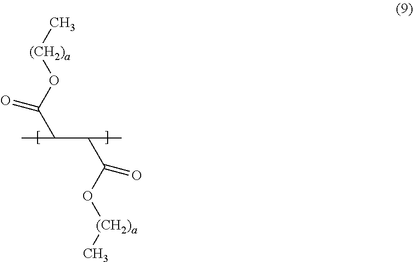

(In Formula (9), “a” represents an integer of 2 to 9.)

In the present embodiment, the structural unit represented by the above-described Formula (1b) may be derived from for example, a fumaric acid diester monomer. That is, the first polymer including a structural unit that has an alkoxycarbonyl group bonded to the main chain can be achieved without using maleic anhydride. For this reason, the first polymer may not include a structural unit having an anhydride ring derived from maleic anhydride. Accordingly, it is possible to more effectively improve reworkability, liquid chemical resistance, and transparency of a resin film formed from the photosensitive resin composition.

The first polymer may further include a structural unit represented by the following Formula (2). Accordingly, it is possible to improve balance among various properties required of a resin film serving as a permanent film, such as heat resistance, transparency, a low dielectric constant, low birefringence, chemical resistance, and water repellency. Meanwhile, the first polymer may or may not include a structural unit represented by the following Formula (2).

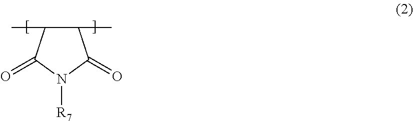

In the above-described Formula (2), R₇ represents hydrogen or an organic group having 1 to 12 carbon atoms. Examples of an organic group having 1 to 12 carbon atoms which constitutes R₇ include a hydrocarbon group having 1 to 12 carbon atoms such as an alkyl group, an alkenyl group, an alkynyl group, an alkylidene group, an aryl group, an aralkyl group, an alkaryl group, or a cycloalkyl group. Examples of the alkyl group include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group. Examples of the alkenyl group include an allyl group, a pentenyl group, and a vinyl group. Examples of the alkynyl group include an ethynyl group. Examples of the alkylidene group include a methylidene group and an ethylidene group. Examples of the aryl group include a phenyl group and a naphthyl group. Examples of the aralkyl group include a benzyl group and a phenethyl group. Examples of the alkaryl group include a tolyl group and a xylyl group. Examples of the cycloalkyl group include an adamantyl group, a cyclopentyl group, a cyclohexyl group, and a cyclooctyl group. Further, one or more hydrogen atoms included in R₇ may be substituted with a halogen atom such as fluorine, chlorine, bromine, or iodine.

In the present embodiment, for example, a polymer which includes a structural unit represented by Formula (2) in which R₇ represents hydrogen and a structural unit represented by Formula (2) in which R₇ represents an organic group having 1 to 12 carbon atoms can be employed as the first polymer. As described below, such a first polymer includes a structural unit represented by the following Formula (1a), a structural unit represented by the following Formula (1b), a structural unit represented by the following Formula (2a), and a structural unit represented by the following Formula (2b). R₇ represented by the following Formula (2b) represents an organic group having 1 to 12 carbon atoms exemplified in Formula (2).

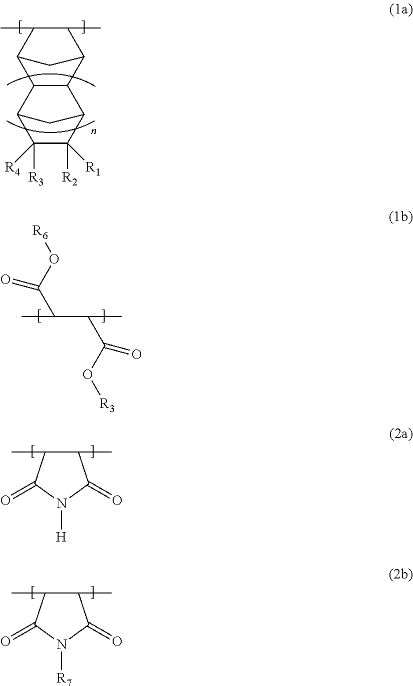

The first polymer may further include a structural unit represented by the following Formula (4). Accordingly, it is possible to more effectively improve crack resistance while improving the balance among various properties required of a resin film serving as a permanent film, such as curability or lithographic performance. Meanwhile, the first polymer may not include a structural unit represented by the following Formula (4).

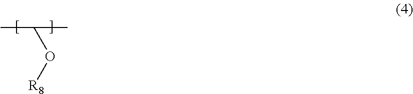

In the above-described Formula (4), R₈ represents an organic group having 1 to 10 carbon atoms. Examples of an organic group constituting R₈ and having 1 to 10 carbon atoms include an organic group containing a glycidyl group or an oxetane group, and an alkyl group. Examples of the alkyl group include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group. Examples of the organic group containing an oxetane group include those represented by the following Formula (4a). Examples of the organic group containing a glycidyl group include those represented by the following Formula (4b). From the viewpoint of improving crack resistance or curability, it is more preferable that R₈ represents an organic group having 5 to 10 carbon atoms. Further, one or more hydrogen atoms included in R₈ may be substituted with a halogen atom such as fluorine, chlorine, bromine, or iodine.

An example of a preferred aspect in the present embodiment is a first polymer including a structural unit represented by the above-described Formula (4) in which Re represents an organic group containing a glycidyl group.

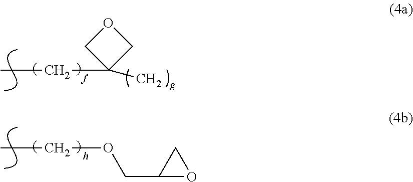

(In the formula, f, g, and h represent an integer of 0 to 5.)

The first polymer may further include a structural unit represented by the following Formula (10). Accordingly, it is possible to reliably suppress the occurrence of an undercut in the patterning process performed on a resin film formed from the photosensitive resin composition. In other words, it is possible to more effectively improve undercut resistance. Meanwhile, the first polymer may or may not include the structural unit represented by the following Formula (10).

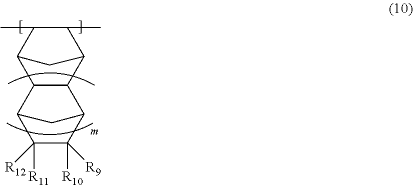

In Formula (10), m represents 0, 1, or 2. R₉, R₁₀, R₁₁, and R₁₂ each independently represent hydrogen or a C1-C10 organic group which does not include any of a carboxyl group, an epoxy ring, and an oxetane ring. Examples of the C1-C10 organic group that constitutes R₉, R₁₀, R₁₁, and R₁₂ include an alkyl group, an alkenyl group, an alkynyl group, an alkylidene group, an aryl group, an aralkyl group, an alkaryl group, a cycloalkyl group, an alkoxysilyl group, and a heterocyclic group other than an epoxy group and an oxetane group. Examples of the alkyl group include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group. Examples of the alkenyl group include an allyl group, a pentenyl group, and a vinyl group. Examples of the alkynyl group include an ethynyl group. Examples of the alkylidene group include a methylidene group and an ethylidene group. Examples of the aryl group include a phenyl group and a naphthyl group. Examples of the aralkyl group include a benzyl group and a phenethyl group. Examples of the alkaryl group include a tolyl group and a xylyl group. Examples of the cycloalkyl group include an adamantyl group, a cyclopentyl group, a cyclohexyl group, and a cyclooctyl group. Further, in the alkyl group, the alkenyl group, the alkynyl group, the alkylidene group, the aryl group, the aralkyl group, the alkaryl group, the cycloalkyl group, the alkoxysilyl group, and the heterocyclic group, one or more hydrogen atoms may be substituted with a halogen atom such as fluorine, chlorine, bromine, or iodine.

An example of a preferred aspect in the present embodiment is a first polymer including a structural unit represented by the above-described Formula (10) in which at least one of R₉, R₁₀, R₁₁, and R₁₂ represents an alkoxysilyl group. From the viewpoint of more effectively improving undercut resistance, it is particularly preferable that any one of R₉, R₁₀, R₁₁, and R₁₂ represents an alkoxysilyl group and the rest represents hydrogen.

It is more preferable that the alkoxysilyl group constituting R₉, R₁₀, R₁₁, and R₁₂ is a trialkoxysilyl group. Accordingly, it is possible to more effectively improve undercut resistance. In the present embodiment, as the trialkoxysilyl group constituting R₉, R₁₀, R₁₁, and R₁₂, for example, those represented by the following Formula (10a) can be employed.

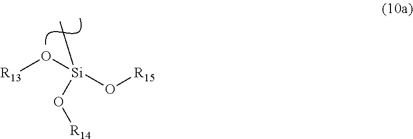

In the above-described Formula (10a), R₁₃, R₁₄, and R₁₅ each independently represent an alkyl group having 1 to 6 carbon atoms. Examples of the alkyl group include a methyl group, an ethyl group, an n-propyl group, an isopropyl group, an n-butyl group, an isobutyl group, a sec-butyl group, a tert-butyl group, a pentyl group, a neopentyl group, and a hexyl group. In the present embodiment, R₁₃, R₁₄, R₁₅, may be the same as each other.

Further, within the range not inhibiting the effects of the present invention, the first polymer may include structural units other than the structural unit represented by the above-described Formula (1a), the structural unit represented by the above-described Formula (1b), the structural unit represented by the above-described Formula (2), the structural unit represented by the above-described Formula (4), and the structural unit represented by the above-described Formula (10).

The first polymer may include one or two or more kinds, as a low molecular weight component, selected from a monomer represented by the following Formula (11), a monomer represented by the following Formula (12), a monomer represented by the following Formula (13), a monomer represented by the following Formula (14), and a monomer represented by the following Formula (15).

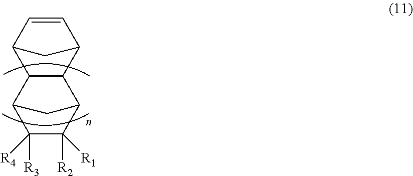

(In Formula (11), n, R₁, R₂, R₃, and R₄ may represent those exemplified in the above-described Formula (1a).)

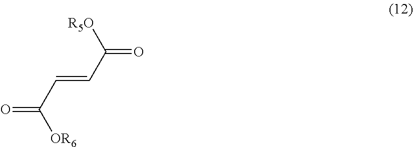

(In Formula (12), R₅ and R₆ may represent those exemplified in the above-described Formula (1b).)

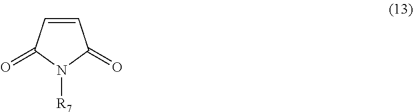

(In Formula (13), R₇ may represent those exemplified in the above-described Formula (2).)

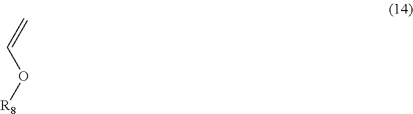

(In Formula (14), R₈ may represent those exemplified in the above-described Formula (4).)

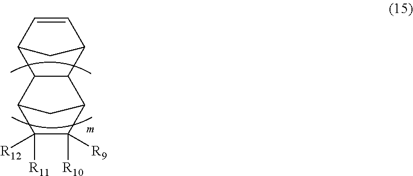

(In Formula (15), m, R₉, R₁₀, R₁₁, and R₁₂, may represent those exemplified in the above-described Formula (10).)

The first polymer can be synthesized, for example, in the following manner.

First, a compound represented by the above-described Formula (11) and a compound represented by the above-described Formula (12) are prepared. Further, if necessary, a compound represented by the above-described Formula (13), a compound represented by the above-described Formula (14), a compound represented by the above-described Formula (15), and one or two or more kinds of other compounds may be prepared. Further, in the present embodiment, for example, a synthesis method that does not use maleic anhydride as a monomer for synthesizing the first polymer can be employed. In this manner, the first polymer can be made not to include a structural unit having an anhydride ring derived from maleic anhydride.

Next, the compound represented by the above-described Formula (11) and the compound represented by the above-described Formula (12) are subjected to addition polymerization, thereby obtaining a copolymer (copolymer 1) of these compounds. Here, the addition polymerization is performed through, for example, radical polymerization. In the present embodiment, solution polymerization can be performed by, for example, dissolving the compound represented by the above-described Formula (10), the compound represented by the above-described Formula (11), and a polymerization initiator in a solvent and heating the solution for a predetermined time. At this time, the heating temperature can be set to a range of 50° C. to 80° C., for example. Moreover, the heating can be set to a range of 1 to hours. Further, it is more preferable that the solution polymerization is performed after dissolved oxygen in the solvent is removed by nitrogen bubbling.

Further, a molecular weight regulator or a chain transfer agent can be used as needed. Examples of the chain transfer agent may include thiol compounds such as dodecyl mercaptan, mercaptoethanol, and 4,4-bis(trifluoromethyl)-4-hydroxy-1-mercaptobutane. These chain transfer agents may be used alone or in combination of two or more kinds thereof.

As the solvent used in the solution polymerization, one or two or more kinds selected from methyl ethyl ketone (MEK), propylene glycol monomethyl ether, propylene glycol monomethyl ether acetate, diethyl ether, tetrahydrofuran (THF), and toluene can be used. Further, as the polymerization initiator, one or two or more kinds selected from an azo compound and an organic peroxide can be used. Examples of the azo compound include azobisisobutyronitrile (AIBN), dimethyl 2,2′-azobis(2-methylpropionate), and 1,1′-azobis(cyclohexanecarbonitrile) (ABCN). Examples of the organic peroxide include hydrogen peroxide, ditertiary butyl peroxide (DTBP), benzoyl peroxide (BPO), and methyl ethyl ketone peroxide (MEKP).

The reaction solution including the copolymer 1 obtained in the above-described manner is added to hexane or methanol so that a polymer is precipitated. Next, the polymer is filtered off, washed with hexane or methanol, and dried. In the present embodiment, the first polymer can be synthesized in the above-described manner.

(Photosensitive Resin Composition)

A photosensitive resin composition is used to form a permanent film.

The above-described permanent film is formed of a resin film obtained by curing the photosensitive resin composition. In the present embodiment, for example, a coating film formed of the photosensitive resin composition is patterned to have a desired shape through exposure and development and then cured by carrying out a heat treatment or the like, thereby obtaining a permanent film.

As the permanent film formed using the photosensitive resin composition, an interlayer film, a surface protective film, or a dam material may be exemplified. Further, the permanent film can be used as an optical material such as an optical lens. However, the applications of the permanent film are not limited thereto.

The interlayer film indicates an insulating film provided in a multilayer structure and the type thereof is not particularly limited. Examples of the applications of the interlayer film include use in semiconductors, for example, as an interlayer insulating film constituting a multilayer wiring structure of a semiconductor element, and a film used in a build-up layer or a core layer constituting a circuit board, and moreover, use in display devices, for example, as a planarization film covering a thin film transistor (TFT) in a display device, a liquid crystal alignment film, a projection provided on a color filter substrate of a multi domain vertical alignment (MVA) type liquid crystal display device, and a partition wall for forming a cathode of an organic EL element.

The surface protective film is formed on the surface of an electronic component or an electronic device and indicates an insulating film used for protecting the surface of the component or device, the type thereof being not particularly limited. Examples of such a surface protective film include a passivation film, a bump protective film, or a buffer coat layer provided on a semiconductor element, and a cover coat provided on a flexible substrate. In addition, the dam material is a spacer used to form a hollow portion for disposing an optical element or the like on a substrate.

The photosensitive resin composition includes the first polymer.

As the first polymer, those exemplified above can be used. The photosensitive resin composition according to the present embodiment may include one or two or more kinds selected from those exemplified as the first polymer above. The content of the first polymer in the photosensitive resin composition is not particularly limited, but is preferably equal to or greater than 20% by mass and equal to or less than 90% by mass and more preferably equal to or greater than 30% by mass and equal to or less than 80% by mass with respect to the total solid content of the photosensitive resin composition. Further, the solid content of the photosensitive resin composition indicates components excluding the solvent included in the photosensitive resin composition. Hereinafter, the same applies in the present specification.

The photosensitive resin composition may include a photosensitizer.

The photosensitizer may include a diazoquinone compound. Examples of the diazoquinone compound used as a photosensitizer include compounds shown below.

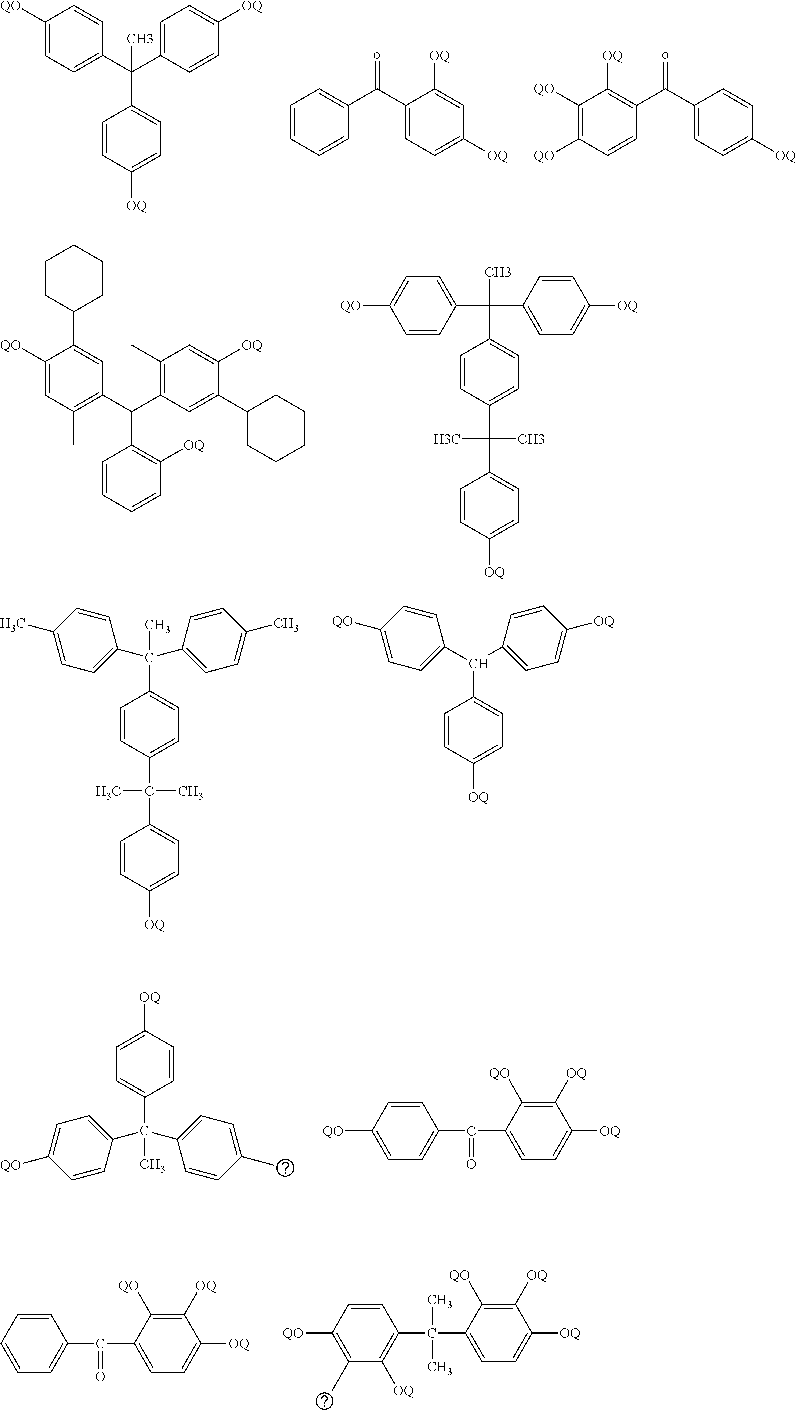

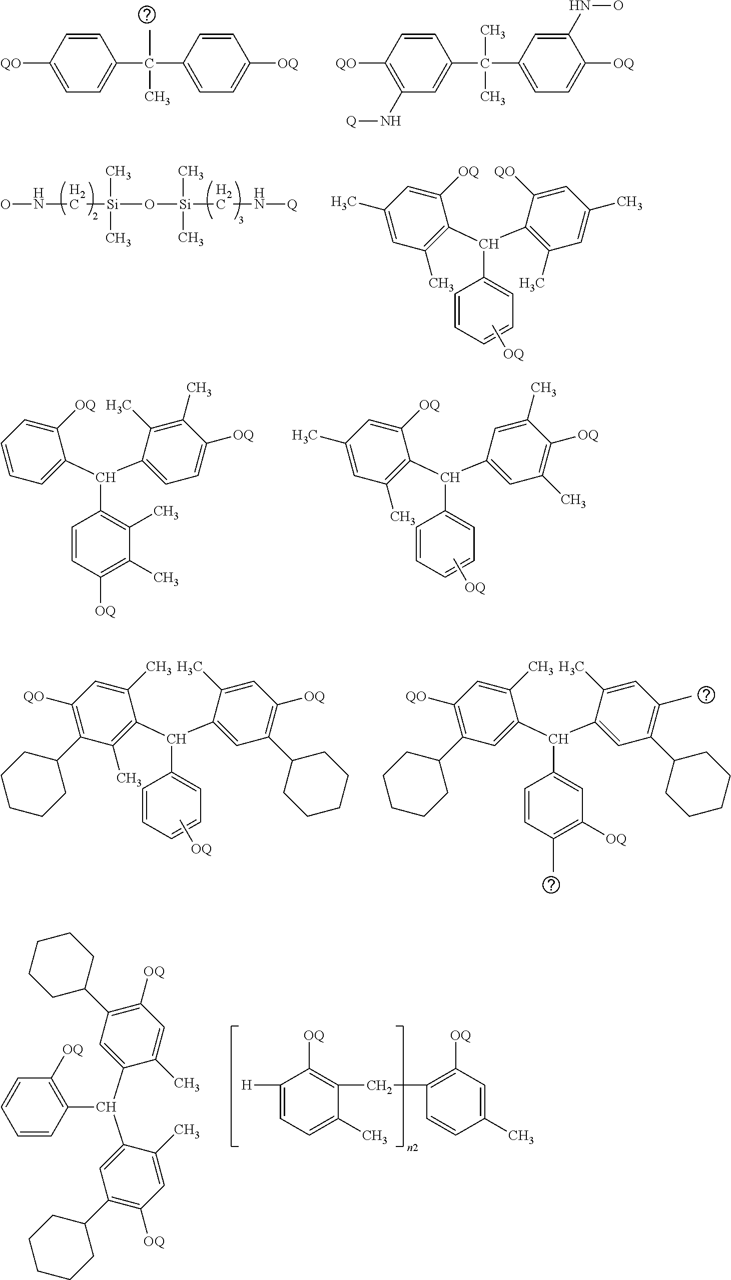

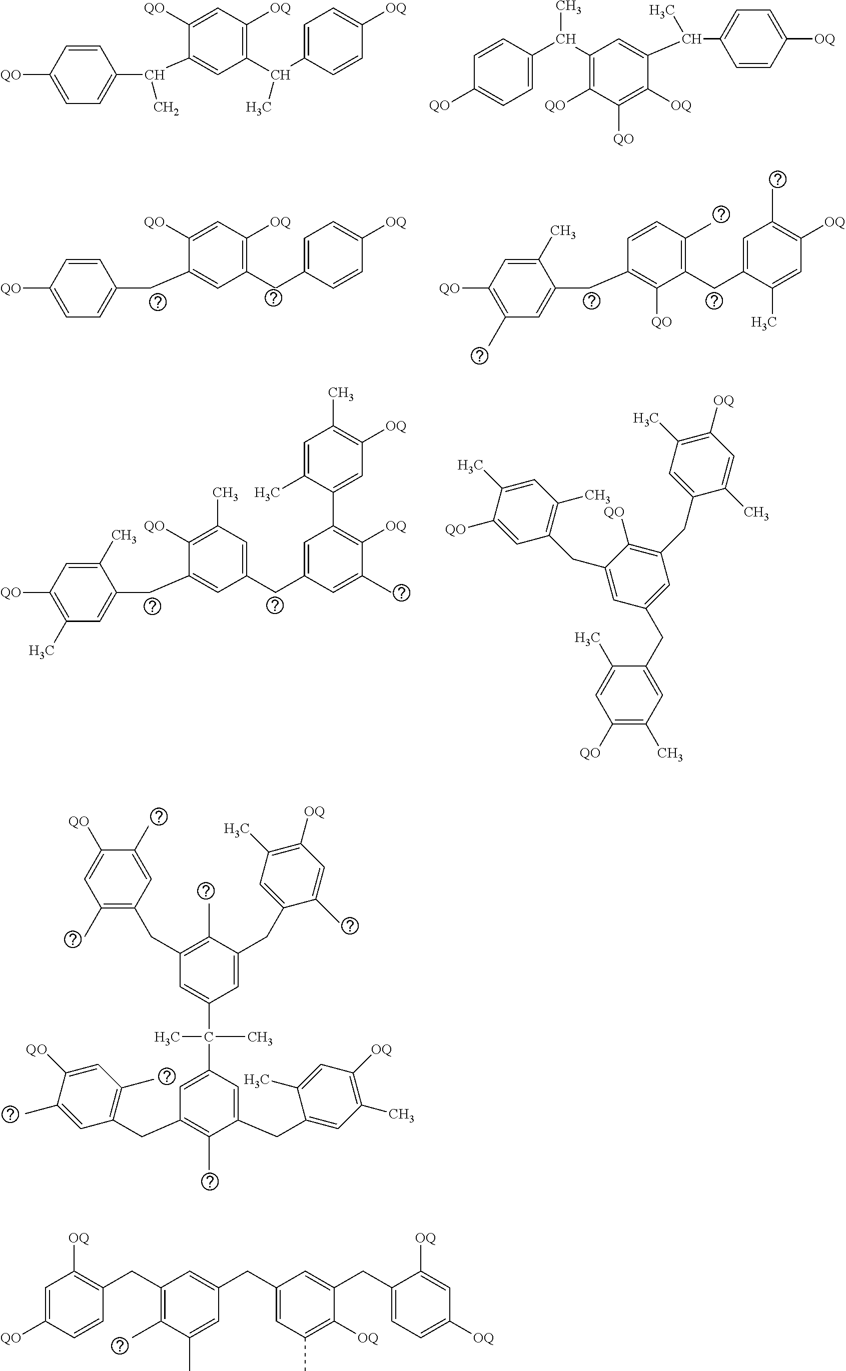

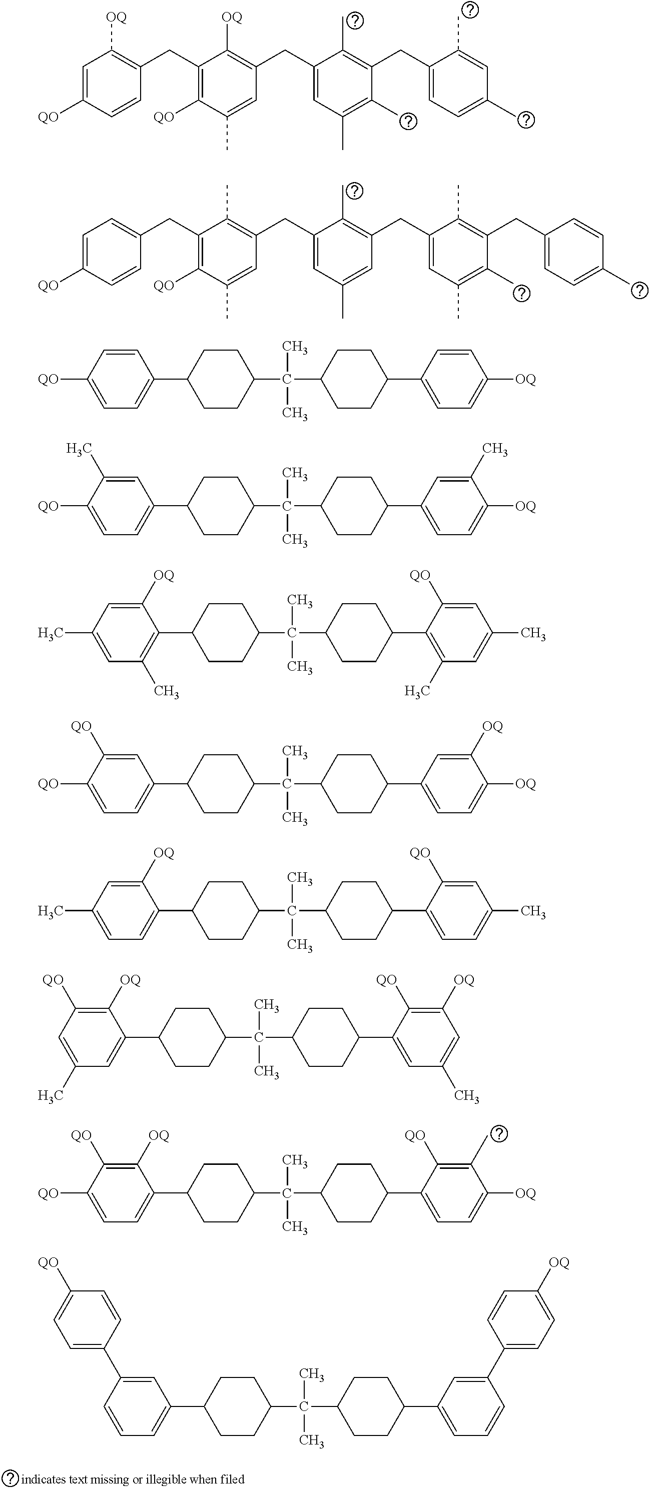

(n2 represents an integer of 1 to 5.)

In each of the above-described compounds, Q represents any of the following structure (a), structure (b), and structure (c), or a hydrogen atom. In this case, at least one Q included in the respective compounds represents any of the structure (a), the structure (b), and the structure (c). From the viewpoints of transparency and the dielectric constant of the photosensitive resin composition, an o-naphthoquinone diazide sulfonic acid derivative in which Q represents the structure (a) or the structure (b) is more preferable.

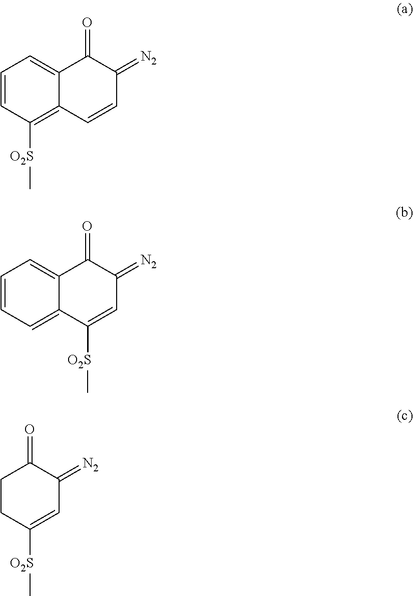

The content of the photosensitizer in the photosensitive resin composition is preferably equal to or greater than 1% by mass and equal to or less than 40% by mass and more preferably equal to or greater than 5% by mass and equal to or less than 30% by mass with respect to the total solid content of the photosensitive resin composition. It is thus possible to effectively improve the balance between the reactivity and reworkability or developability of the photosensitive resin composition.

The photosensitive resin composition may include an acid generator that generates an acid through, for example, light or heat. Examples of the photoacid that generates an acid through light include compounds, for example, sulfonium salts such as triphenylsulfonium trifluoromethanesulfonate, tris(4-t-butylphenyl)sulfonium-trifluoromethanesulfonate, and diphenyl[4-(phenylthio)phenyl]sulfoniumtetrakis(pentafluorophenyl)borate; diazonium salts such as p-nitrophenyl diazonium hexafluorophosphate; ammonium salts; phosphonium salts; iodonium salts such as diphenyliodonium trifluoromethanesulfonate, and (tricumyl)iodonium-tetrakis(pentafluorophenyl)borate; quinonediazides; diazomethanes such as bis(phenylsulfonyl)diazomethane; sulfonic acid esters such as 1-phenyl-1-(4-methylphenyl)sulfonyloxy-1-benzoylmethane and N-hydroxynaphthalimide-trifluoromethanesulfonate; disulfones such as diphenyl disulfone; and triazines such as tris(2,4,6-trichloromethyl)-s-triazine, and 2-(3,4-methylenedioxyphenyl)-4,6-bis-(trichloromethyl)-s-triazin e. The photosensitive resin composition of the present embodiment may include one or two or more kinds of photoacid generators exemplified above.

As the acid generator (thermal acid generator) that generates an acid through heat, the photosensitive resin composition may have aromatic sulfonium salts such as SI-45L, SI-60L, SI-80L, SI-100L, SI-110L, and SI-150L (manufactured by SANSHIN CHEMICAL INDUSTRY CO., LTD.). The photosensitive resin composition of the present embodiment may include one or two or more kinds of the thermal acid generator exemplified above. Moreover, in the present embodiment, the photoacid generators exemplified above and these thermal acid generators can be used in combination.

The content of the acid generator in the photosensitive resin composition is preferably equal to or greater than 0.1% by mass and equal to or less than 15% by mass and more preferably equal to or greater than 0.5% by mass and equal to or less than 10% by mass with respect to the total solid content of the photosensitive resin composition. In this manner, it is possible to effectively improve the balance between the reactivity and reworkability of the photosensitive resin composition.

The photosensitive resin composition may include a crosslinking agent. Accordingly, it is possible to improve curability and contribute to mechanical properties of a cured film. The crosslinking agent preferably contains a compound having a heteroring as a reactive group. Among such compounds, a compound having a glycidyl group or an oxetanyl group is preferable. Among these, from the viewpoint of reactivity with a functional group having active hydrogen such as a carboxyl group or a hydroxyl group, it is more preferable that the crosslinking agent includes a compound having a glycidyl group.

As the compound having a glycidyl group used as a crosslinking agent, an epoxy compound may be exemplified. Examples of the epoxy compound include glycidyl ether such as n-butyl glycidyl ether, 2-ethoxyhexyl glycidyl ether, phenyl glycidyl ether, allyl glycidyl ether, ethylene glycol diglycidyl ether, propylene glycol diglycidyl ether, neopenthyl glycol diglycidyl ether, glycerol polyglycidyl ether, sorbitol polyglycidyl ether, or glycidyl ether of bisphenol A (or F); glycidyl ester such as adipic acid diglycidyl ester or o-phthalic acid diglycidyl ester; alicyclic epoxy such as 3,4-epoxycyclohexylmethyl(3,4-epoxycyclohexane)carboxylate, 3,4-epoxy-6-methylcyclohexylmethyl(3,4-epoxy-6-methylcyclohexane)carboxylate, bis(3,4-epoxy-6-methylcyclohexylmethyl)adipate, dicyclopentanedieneoxide, bis(2,3-epoxycyclopentyl)ether, CELLOXIDE 2021, CELLOXIDE 2081, CELLOXIDE 2083, CELLOXIDE 2085, CELLOXIDE 8000, or EPOLEAD GT401 (manufactured by Daicel Corporation); aliphatic polyglycidyl ether such as 2,2′-((((1-(4-(2-(4-(oxirane-2-ylmethoxy)phenyl)propane-2-yl)phenyl)ethane-1,1-diyl)bis(4,1-phenylene)bis(oxy))bis(methylene))bis(oxirane) (such as Techmore VG3101L (manufactured by Printec Corporation)), EPOLIGHT 100MF (manufactured by KYOEISHA CHEMICAL Co., LTD.), or EPIOL TMP (manufactured by NOF CORPORATION); and 1,1,3,3,5,5-hexamethyl-1,5-bis(3-(oxirane-2-ylmethoxy)propyl)tri siloxane (such as DMS-E09 (manufactured by Gelest, Inc.)).

Further, other examples thereof include a bisphenol A type epoxy resin such as LX-01 (manufactured by DAISO CO., LTD.), jER1001, jER1002, jER1003, jER1004, jER1007, jER1009, jER1010, or jER828 (trade name, manufactured by Mitsubishi Chemical Corporation); a bisphenol F type epoxy resin such as jER807 (trade name, manufactured by Mitsubishi Chemical Corporation); a phenol novolac type epoxy resin such as jER152, jER154 (trade name, manufactured by Mitsubishi Chemical Corporation), EPPN201, or EPPN202 (trade name, manufactured by Nippon Kayaku Co., Ltd.); a cresol novolac type epoxy resin such as EOCN102, EOCN103S, EOCN104S, EOCN1020, EOCN1025, EOCN1027 (trade name, manufactured by Nippon Kayaku Co., Ltd.), or jER157S70 (trade name, manufactured by Mitsubishi Chemical Corporation); a cyclic aliphatic epoxy resin such as ARALDITE CY179, ARALDITE CY184 (trade name, manufactured by Huntsman Advanced Materials), ERL-4206, ERL-4221, ERL-4234, ERL-4299 (trade name, manufactured by Dow Chemical Company), EPICLON 200, EPICLON 400 (trade name, manufactured by DIC Corporation), jER871, or jER872 (trade name, manufactured by Mitsubishi Chemical Corporation); a polyfunctional alicyclic epoxy resin such as Poly[(2-oxiranyl)-1,2-cyclohexanediol]2-ethyl-2-(hydroxymethyl)-1,3-propanediol ether (3:1); and EHPE-3150 (manufactured by Daicel Corporation).

Moreover, the photosensitive resin composition of the present embodiment may include one or two or more kinds of epoxy compounds exemplified above.

Examples of the compound having an oxetanyl compound used as a crosslinking agent include 1,4-bis{[(3-ethyl-3-oxetanyl)methoxy]methyl}benzene, bis[1-ethyl(3-oxetanyl)]methyl ether, 4,4′-bis[(3-ethyl-3-oxetanyl)methoxymethyl]biphenyl, 4,4′-bis(3-ethyl-3-oxetanylmethoxy)biphenyl, ethylene glycol bis(3-ethyl-3-oxetanylmethyl)ether, diethylene glycol bis(3-ethyl-3-oxetanylmethyl)ether, bis(3-ethyl-3-oxetanylmethyl)diphenoate, trimethylolpropanetris(3-ethyl-3-oxetanylmethyl)ether, pentaerythritol tetrakis(3-ethyl-3-oxetanylmethyl)ether, a poly[[3-[(3-ethyl-3-oxetanyl)methoxy]propyl]silasesquioxane] derivative, oxetanyl silicate, phenol novolac type oxetane, and 1,3-bis[(3-ethyloxetane-3-yl)methoxy]benzene, but examples are not limited to these. These may be used alone or in combination of plural kinds thereof.

In the present embodiment, the content of the crosslinking agent in the photosensitive resin composition is preferably 1% by mass or greater and more preferably 5% by mass or greater with respect to the total solid content of the photosensitive resin composition. Meanwhile, the content of the crosslinking agent in the photosensitive resin composition is preferably 50% by mass or less and more preferably 40% by mass or less with respect to the total solid content of the photosensitive resin composition. When the content of the crosslinking agent is adjusted to the above-described range, it is possible to more effectively improve the balance between the reactivity and the temporal stability of the photosensitive resin composition.

The photosensitive resin composition may include an adhesion assistant. The adhesion assistant is not particularly limited, and examples thereof include a silane coupling agent such as aminosilane, epoxysilane, acrylsilane, mercaptosilane, vinylsilane, ureido silane, or sulfidesilane. These may be used alone or in combination of two or more kinds thereof. Among these, from the viewpoint of effectively improving the adhesion to other members, it is more preferable to use epoxysilane.

Examples of the aminosilane include bis(2-hydroxyethyl)-3-aminopropyltriethoxysilane, γ-aminopropyltriethoxysilane, γ-aminopropyltrimethoxysilane, γ-aminopropylmethyldiethoxysilane, γ-aminopropylmethyldimethoxysilane, N-β(aminoethyl)γ-aminopropyltrimethoxysilane, N-β(aminoethyl)γ-aminopropyltriethoxysilane, N-β(aminoethyl)γ-aminopropylmethyldimethoxysilane, N-β(aminoethyl)γ-aminopropylmethyldiethoxysilane, and N-phenyl-γ-amino-propyltrimethoxysilane. Examples of the epoxysilane include γ-glycidoxypropyltrimethoxysilane, γ-glycidoxypropylmethyldiethoxysilane, and β-(3,4-epoxycyclohexyl)ethyltrimethoxysilane. Examples of the acrylsilane include γ-(methacryloxypropyl)trimethoxysilane, γ-(methacryloxypropyl)methyldimethoxysilane, and γ-(methacryloxypropyl)methyldiethoxysilane. Examples of the mercaptosilane include γ-mercaptopropyltrimethoxysilane. Examples of the vinylsilane include vinyltris(β-methoxyethoxy)silane, vinyltriethoxysilane, and vinyltrimethoxysilane. Examples of the ureidosilane include 3-ureidopropyltriethoxysilane. Examples of the sulfidesilane include bis(3-(triethoxysilyl)propyl)disulfide and bis(3-(triethoxysilyl)propyl)tetrasulfide.

In the present embodiment, the content of the adhesion assistant in the photosensitive resin composition is preferably 0.1% by mass or greater and more preferably 0.5% by mass or greater with respect to the total solid content of the photosensitive resin composition. Meanwhile, the content of the adhesion assistant in the photosensitive resin composition is preferably 20% by mass or less and more preferably 15% by mass or less with respect to the total solid content of the photosensitive resin composition. When the content of the adhesion assistant is adjusted to the above-described range, it is possible to more effectively improve the adhesion of a cured film, formed from the photosensitive resin composition, to other members.

The photosensitive resin composition may include a surfactant. The surfactant includes a compound including a fluorine group (such as a fluorinated alkyl group) or a silanol group, or a compound having a siloxane bond as a main skeleton. In the present embodiment, it is more preferable that the photosensitive resin composition includes a fluorine-based surfactant or a silicone-based surfactant as a surfactant and particularly preferable that the photosensitive resin composition includes a fluorine-based surfactant as a surfactant. Examples of the surfactant include MEGAFACE F-554, MEGAFACE F-556, and MEGAFACE F-557 (manufactured by DIC Corporation), but the present invention is not limited thereto.

In the present embodiment, the content of the surfactant in the photosensitive resin composition is preferably 0.1% by mass or greater and more preferably 0.2% by mass or greater with respect to the total solid content of the photosensitive resin composition. Meanwhile, the content of the surfactant in the photosensitive resin composition is preferably 3% by mass or less and more preferably 2% by mass or less with respect to the total solid content of the photosensitive resin composition. When the content of the surfactant is adjusted to the above-described range, the flatness of the photosensitive resin composition can be effectively improved. In addition, at the time of spin-coating, it is possible to prevent the occurrence of radial striations on the coating film.

Moreover, additives such as an antioxidant, a filler, and a sensitizer may be added to the photosensitive resin composition as needed. The photosensitive resin composition may include, as an antioxidant, one or two or more kinds selected from the group consisting of a phenolic antioxidant, a phosphorus-based antioxidant, and a thioether-based antioxidant. The photosensitive resin composition may include, as a filler, one or two or more kinds selected from inorganic fillers such as silica. The photosensitive resin composition may include, as a sensitizer, one or two or more kinds selected from the group consisting of anthracenes, xanthones, anthraquinones, phenanthrenes, chrysenes, benzopyrenes, fluoracenes, rubrenes, pyrenes, indanthrenes, and thioxanthene-9-ones.

The photosensitive resin composition may include a solvent. In this case, the photosensitive resin composition becomes varnish-like. The photosensitive resin composition may include, as a solvent, one or two or more kinds selected from propylene glycol monomethyl ether (PGME), propylene glycol monomethyl ether acetate (PGMEA), ethyl lactate, methyl isobutyl carbinol (MIBC), gamma butyrolactone (GBL), N-methylpyrrolidone (NMP), methyl n-amyl ketone (MAK), diethylene glycol monomethyl ether, diethylene glycol dimethyl ether, diethylene glycol methyl ethyl ether, and benzyl alcohol. In addition, the solvent which can be used in the present embodiment is not limited to these.

For example, a positive type photosensitive resin composition can be used as the photosensitive resin composition according to the present embodiment. Thus, a fine pattern can be more easily formed at the time when a resin film formed from the photosensitive resin composition is patterned according to a lithographic method. Further, it is also possible to contribute to a low dielectric constant of the resin film. Moreover, since a post exposure bake treatment (PEB) becomes unnecessary when the lithographic method is performed, compared to a negative type photosensitive resin composition described below, the number of processes can be reduced.

In a case where the photosensitive resin composition is a positive type photosensitive resin composition, the composition includes, for example, the first polymer and a photosensitizer. Further, the positive type photosensitive resin composition may include an acid generator in addition to the first polymer and the photosensitizer. Accordingly, the curability of the photosensitive resin composition can be more effectively improved. Furthermore, the positive type photosensitive resin composition may further include each of the components exemplified above other than the first polymer, the photosensitizer, and the acid generator.

For example, the patterning can be performed on a resin film formed from the positive type photosensitive resin composition in the following manner. First, an exposure treatment is performed on a resin film obtained by pre-baking the coating film of the photosensitive resin composition. Next, a development treatment is performed on the exposed resin film using a developer, and the resin film is rinsed with pure water. In this manner, the resin film on which a pattern is formed can be obtained.

For example, the photosensitive resin composition according to the present embodiment may be a negative type photosensitive resin composition. Accordingly, it is possible to more effectively improve transparency or liquid chemical resistance of a resin film formed from the photosensitive resin composition. In a case where the photosensitive resin composition is a negative type photosensitive resin composition, the composition includes, for example, the first polymer and a photoacid generator. Meanwhile, the negative type photosensitive resin composition does not include a photosensitizer. Further, the negative type photosensitive resin composition may include each of the components exemplified above other than the first polymer, the photoacid generator, and the photosensitizer.

For example, the patterning can be performed on a resin film formed from the negative type photosensitive resin composition in the following manner. First, an exposure treatment is performed on a resin film obtained by pre-baking the coating film of the photosensitive resin composition. Next, a post exposure bake (PEB) treatment is performed on the exposed resin film. In this manner, the crosslinking reaction of the first polymer is accelerated and insolubilization of a portion irradiated with light can be promoted. Further, the conditions of PEB are not particularly limited, but PEB can be carried out under the conditions of a temperature range of 100° C. to 150° C. for 120 seconds. Next, after a development treatment is performed on the resin film, to which the PEB treatment has been applied, using a developer, the resin film is rinsed with pure water. In this manner, the resin film on which a pattern is formed can be obtained.

It is preferable that the above-described photosensitive resin composition has physical properties described below. These physical properties can be achieved by suitably adjusting the type or the content of each component included in the photosensitive resin composition.

(1) Residual Film Rate

The residual film rate of the photosensitive resin composition after development is preferably 80% or greater. In addition, the residual film rate of the photosensitive resin composition after post-baking is preferably 70% or greater. Accordingly, a pattern having a desired shape can be achieved with excellent precision. The upper limit of the residual film rate after development or the residual film rate after post-baking is not particularly limited, but may be set to, for example, 99%.

The residual film rate can be measured in the following manner. First, a glass substrate is spin-coated with the photosensitive resin composition and heated at 100° C. for 120 seconds using a hot plate, and a resin film obtained in this manner is referred to as a thin filmA. Next, the resin film is exposed to light at an optimum exposure amount such that the ratio of the line width to the space width of 5 μm is set to 1:1 using an exposure device. In a case where the photosensitive resin composition is a negative photosensitive resin composition, the thin film A after exposure to light is baked on a hot plate in a temperature range of 100° C. to 150° C. for 120 seconds. Next, the thin film A is developed at 23° C. for 90 seconds using a developer, thereby obtaining a thin film B. Subsequently, the entire surface of the thin film B is exposed to light using g+h+i line at 300 mJ/cm² and subjected to a post bake treatment by heating in an oven at 230° C. for 60 minutes, thereby obtaining a thin film C. In addition, the residual film rate is calculated using the following equations from the film thicknesses of the measured thin film A, thin film B, and thin film C.

Residual film rate after development (%)=[film thickness (μm) of thin film B/film thickness (μm) of thin film A]]×100

Residual film rate after baking (%)=[film thickness (μm) of thin film C/film thickness (μm) of thin film A]]×100

(2) Relative Dielectric Constant

The relative dielectric constant of the resin film formed using the photosensitive resin composition is, for example, preferably 5.0 or less. In addition, the lower limit of the relative dielectric constant is not particularly limited, but can be set to 1.0.

In the positive type photosensitive resin composition, the relative dielectric constant thereof can be measured in the following manner. First, an aluminum substrate is spin-coated with the photosensitive resin composition and baked on a hot plate at 100° C. for 120 seconds, thereby obtaining a resin film. Next, the entire surface of the film is exposed to light using g+h+i line at 300 mJ/cm² and subjected to a post baking treatment by heating in an oven at 230° C. for 60 minutes, thereby obtaining a film having a thickness of 3 μm. Thereafter, a gold electrode is formed on the film and the relative dielectric constant is measured using an LCR meter under the conditions of room temperature (25° C.) and 10 kHz.

In the negative type photosensitive resin composition, the relative dielectric constant thereof can be measured in the following manner. First, an aluminum substrate is spin-coated with the photosensitive resin composition and baked on a hot plate at 100° C. for 120 seconds, thereby obtaining a resin film. Next, the entire surface of the resin film is exposed to light using g+h+i line at 300 mJ/cm². Next, the resin film after exposure to light is baked on a hot plate in a temperature range of 100° C. to 150° C. for 120 seconds and then subjected to a post baking treatment by heating in an oven at 230° C. for 60 minutes, thereby obtaining a film having a thickness of 3 μm. Thereafter, a gold electrode is formed on the film and the relative dielectric constant is measured using an LCR meter under the conditions of room temperature (25° C.) and 10 kHz.

(3) Transmittance

The light transmittance of the resin film formed using the photosensitive resin composition at a wavelength of 400 nm is preferably 80% or greater and more preferably 85% or greater. In addition, the upper limit of the transmittance is not particularly limited, but can be set to 99.9%.

In the positive type photosensitive resin composition, the transmittance can be measured in the following manner. First, a glass substrate is spin-coated with the photosensitive resin composition and baked on a hot plate at 100° C. for 120 seconds, thereby obtaining a resin film. Next, the resin film is immersed in a developer for 90 seconds, and then rinsed with pure water. Subsequently, the entire surface of the resin film is exposed to light using g+h+i line at 300 mJ/cm² and subjected to a post baking treatment by heating in an oven at 230° C. for 60 minutes. Further, the light transmittance of the resin film at a wavelength of 400 nm is measured using an ultraviolet-visible light spectrophotometer, and the numerical value converted into a transmittance for a film thickness of 3 μm is set to the transmittance.

In the negative type photosensitive resin composition, the transmittance can be measured in the following manner. First, a glass substrate is spin-coated with the photosensitive resin composition and baked on a hot plate at 100° C. for 120 seconds, thereby obtaining a resin film. Subsequently, the entire surface of the resin film is exposed to light using g+h+i line at 300 mJ/cm². Next, the resin film after exposure to light is baked on a hot plate in a temperature range of 100° C. to 150° C. for 120 seconds. Next, the resin film is immersed in a developer for 90 seconds, and then rinsed with pure water. Subsequently, the resin film is subjected to a post bake treatment by heating in an oven at 230° C. for 60 minutes. Further, the light transmittance of the resin film at a wavelength of 400 nm is measured using an ultraviolet-visible light spectrophotometer, and the numerical value converted into a transmittance for a film thickness of 3 μm is set to the transmittance.

(4) Swelling Rate and Recovery Rate

The swelling rate of the photosensitive composition is preferably equal to or less than 20%. Further, the recovery rate of the photosensitive resin composition is preferably equal to or greater than 95% and equal to or less than 105%. Accordingly, the photosensitive resin composition having excellent chemical resistance is achieved. Further, the lower limit of the swelling rate is not particularly limited, but can be set to, for example, 0%.

In the positive type photosensitive resin composition, the swelling rate and the recovery rate can be measured in the following manner. First, a glass substrate is spin-coated with the photosensitive resin composition and pre-baked on a hot plate at 100° C. for 120 seconds, thereby obtaining a resin film. Next, the resin film is immersed in a developer for 90 seconds, and then rinsed with pure water. Subsequently, the entire surface of the resin film is exposed to light such that the amount of integrated light of g+h+i line became 300 mJ/cm². Next, the resin film is subjected to a thermosetting treatment in an oven at 230° C. for 60 minutes. Further, the film thickness of the cured film obtained in the above-described manner (first film thickness) is measured. Subsequently, the cured film is immersed in TOK106 (manufactured by TOKYO OHKA KOGYO CO., LTD.) at 70° C. for 15 minutes, and then rinsed with pure water for seconds. At this time, the film thickness obtained after the curing film is rinsed is set to a second film thickness and the swelling rate is calculated from the following expression.

Swelling rate: [(second film thickness−first film thickness)/(first film thickness)]×100(%)

Next, the cured film is heated in an oven at 230° C. for 15 minutes and the film thickness after heating (third film thickness) is measured. Further, the recovery rate is calculated from the following expression.

Recovery rate: [(third film thickness)/(first film thickness)]×100(%)

In the negative type photosensitive resin composition, the swelling rate and the recovery rate can be measured in the following manner. First, a glass substrate is spin-coated with the photosensitive resin composition and pre-baked on a hot plate at 100° C. for 120 seconds, thereby obtaining a resin film. Subsequently, the entire surface of the resin film is exposed to light such that the amount of integrated light of g+h+i line became 300 mJ/cm². Next, the resin film after exposure to light is baked on a hot plate in a temperature range of 100° C. to 150° C. for 120 seconds. Subsequently, the resin film is immersed in a developer for 90 seconds, and then rinsed with pure water. Next, the resin film is subjected to a thermosetting treatment in an oven at 230° C. for 60 minutes. Further, the film thickness of the cured film obtained in the above-described manner (first film thickness) is measured. Subsequently, the cured film is immersed in TOK106 (manufactured by TOKYO OHKA KOGYO CO., LTD.) at 70° C. for 15 minutes, and then rinsed with pure water for seconds. At this time, the film thickness obtained after the curing film is rinsed is set to a second film thickness and the swelling rate is calculated from the following expression.

Swelling rate: [(second film thickness−first film thickness)/(first film thickness)]×100(%)

Next, the cured film is heated in an oven at 230° C. for 15 minutes and the film thickness after heating (third film thickness) is measured. Further, the recovery rate is calculated from the following expression.

Recovery rate: [(third film thickness)/(first film thickness)]×100(%)

(5) Sensitivity

The sensitivity of the photosensitive resin composition is preferably equal to or greater than 200 mJ/cm² and equal to or less than 600 mJ/cm². In this manner, it is possible to achieve a photosensitive resin composition having excellent lithographic performance.

In the positive type photosensitive resin composition, the sensitivity can be measured in the following manner. First, a glass substrate is spin-coated with the photosensitive resin composition and baked on a hot plate at 100° C. for 120 seconds, thereby obtaining a thin film having a thickness of approximately 3.5 μm. The thin film is exposed to light using a mask having a hole pattern having a size of 5 μm with an exposure device. In a case where the photosensitive resin composition is a negative photosensitive resin composition, the thin film after exposure to light is baked on a hot plate at 120° C. for 120 seconds. Next, a resist pattern formed by performing development using a developer under the conditions of 23° C. for 90 seconds is observed using an SEM and the exposure amount, at which a hole pattern having a size of 5 μm² is obtained, is set to the sensitivity.

In the negative type photosensitive resin composition, the sensitivity can be measured in the following manner. First, a glass substrate is spin-coated with the photosensitive resin composition and baked on a hot plate at 100° C. for 120 seconds, thereby obtaining a thin film A having a thickness of approximately 3.5 μm. The thin film A is exposed to light by changing the exposure amount by 20 mJ/cm² each time using an exposure device. As the exposure device, for example, a g+h+i line mask aligner (PLA-501F, manufactured by Canon Inc.) can be used. Next, the thin film A after exposure to light is baked on a hot plate in a temperature range of 100° C. to 150° C. for 120 seconds. Next, the film is developed at 23° C. for 90 seconds using a developer and rinsed with pure water, thereby obtaining a thin film B. In addition, the exposure amount satisfying “thin film B/thin film A×100=95%” is set to the sensitivity (mJ/cm²).

(Electronic Device)

Next, an electronic device 100 according to the present embodiment will be described.

The electronic device 100 includes an insulating film 20 which is a permanent film formed from the above-described photosensitive resin composition. The electronic device 100 according to the present embodiment is not particularly limited as long as the device includes an insulating layer formed from the photosensitive resin composition, and examples thereof include a display device including the insulating film 20 as a planarizing film or a micro-lens, and a semiconductor device having a multilayer wiring structure using the insulating film 20 as an interlayer insulating film.

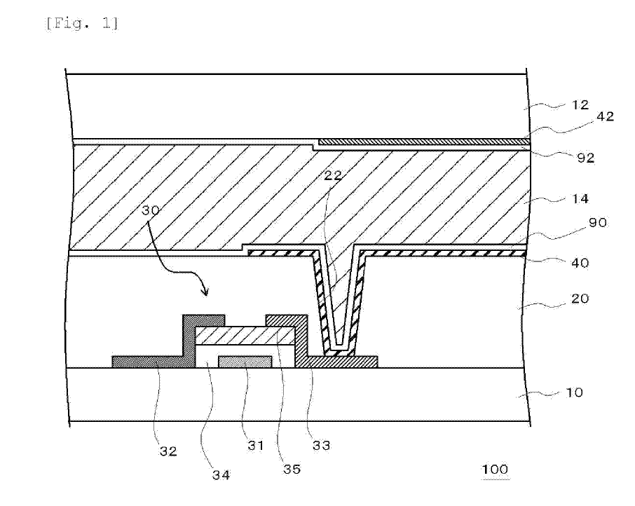

FIG. 1 is a sectional view showing an example of the electronic device 100.

In FIG. 1, a case where the electronic device 100 is a liquid crystal display device and the insulating film 20 is used as a planarizing film is exemplified. The electronic device 100 shown in FIG. 1 includes, for example, a substrate 10, a transistor 30 provided on the substrate 10, the insulating film 20 provided on the substrate 10 such that the transistor 30 is covered, and a wiring provided on the insulating film 20.

The substrate 10 is, for example, a glass substrate. The transistor 30 is, for example, a thin-film transistor constituting a switching element of a liquid crystal device. For example, a plurality of the transistors 30 are disposed in an array on the substrate 10. The transistor 30 shown in FIG. 1 is configured of, for example, a gate electrode 31, a source electrode 32, a drain electrode 33, a gate insulating film 34, and a semiconductor layer 35. The gate electrode 31 is provided, for example, on the substrate 10. The gate insulating film 34 is provided on the substrate 10 such that the gate electrode 31 is covered. The semiconductor layer 35 is provided on the gate insulating film 34. Further, the semiconductor layer 35 is, for example, a silicon layer. The source electrode 32 is provided on the substrate 10 in a state in which a part of the source electrode 32 is in contact with the semiconductor layer 35. The drain electrode 33 is provided on the substrate 10 in a state in which the drain electrode 33 is separated from the source electrode 32 and a part thereof is in contact with the semiconductor layer 35.

The insulating film 20 eliminates a step caused by the transistor or the like and functions as a planarizing film used to form a flat surface on the substrate 10. Further, the insulating film 20 is configured of a cured product of the above-described photosensitive resin composition. The insulating film 20 is provided with an opening 22 passing through the insulating film 20 so as to be connected with the drain electrode 33.

The wiring 40 connected with the drain electrode 33 is formed on the insulating film 20 and inside the opening 22. The wiring 40 functions as a pixel electrode constituting a pixel together with a liquid crystal.

Further, an alignment film 90 is provided on the insulating film such that the wiring 40 is covered.

A counter substrate 12 facing the substrate 10 is disposed above one surface of the substrate 10 on a side on which the transistor is provided. A wiring 42 is provided on one surface of the counter substrate 12, facing the substrate 10. The wiring 42 is provided in a position facing the wiring 40. Moreover, an alignment film 92 is provided on the above-described one surface of the counter substrate 12 such that the wiring 42 is covered.

The space between the substrate 10 and the counter substrate 12 is filled with liquid crystals constituting a liquid crystal layer 14.

The electronic device 100 shown in FIG. 1 can be formed in the following manner.

First, the transistor 30 is formed on the substrate 10. Next, one surface of the substrate 10, provided with the transistor 30, is coated with the photosensitive resin composition according to a printing method or a spin coating method, and the insulating film covering the transistor 30 is formed. Next, the insulating film is subjected to a lithographic treatment and then the insulating film 20 is patterned. In this manner, the opening 22 is formed in a portion of the insulating film 20. Next, the insulating film 20 is heated and cured. In this manner, the insulating film 20 which is a planarizing film is formed on the substrate 10.

Next, the wiring 40 connected to the drain electrode 33 is formed inside the opening 22 of the insulating film 20. Thereafter, the counter substrate 12 is disposed over the insulating film 20 and the space between the counter substrate 12 and the insulating film 20 is filled with liquid crystals, thereby forming the liquid crystal layer 14.

Accordingly, the electronic device 100 shown in FIG. 1 is formed.

Moreover, the present invention is not limited to the above-described embodiments, and modifications and improvements can be made within the range that can achieve the object of the present invention.

### EXAMPLES

Hereinafter, examples of the present invention will be described.

(Synthesis of Polymer)

### Synthesis Example 1

First, (3-ethyloxetan-3-yl)methylbicyclo[2.2.1]hepta-2-ene-5-carboxylic acid (1.18 g, 5 mmol), maleimide (2.18 g, 22.5 mmol), N-cyclohexylmaleimide (4.92 g, 27.5 mmol), norbornene carboxylic acid (2.60 g, 20.0 mmol), methyl glycidyl ether norbornene (3.6 g, 20.0 mmol), and dibutyl fumarate (1.14 g, 5 mmol) were weighed into a reaction container equipped with a stirrer and a cooler. Further, 8.9 g of propylene glycol monomethyl ether acetate in which V-601 (0.92 g, 4.0 mmol) was dissolved was added to the reaction container, and the mixture was stirred and dissolved. Next, after dissolved oxygen in the system was removed by nitrogen bubbling, the container was maintained at 70° C. in a nitrogen atmosphere and the mixture was allowed to react for 5 hours. Subsequently, the reaction mixture was cooled to room temperature, and 30 g of MEK was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 13.4 g and the yield rate thereof was 86%. Further, the weight-average molecular weight Mw of the polymer was 8,800 and the dispersity (weight-average molecular weight Mw/number-average molecular weight Mn) thereof was 2.19.

The obtained polymer has a structure represented by the following Formula (20).

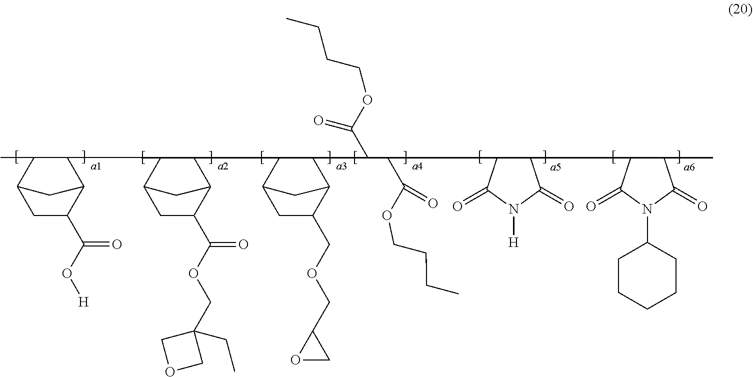

For the weight-average molecular weight (Mw) and the number-average molecular weight (Mn) of the obtained polymer, polystyrene conversion values acquired from the calibration curve of standard polystyrene (PS) obtained by GPC measurement were used. The measurement conditions are as follows.

Gel permeation chromatography device HLC-8320GPC, manufactured by Tohso Co., Ltd.

Column: TSK-GEL Supermultipore HZ-M, manufactured by Tohso Co., Ltd.

Detector: RI detector for liquid chromatogram

Measuring temperature: 40° C.

Solvent: THF

Concentration of sample: 2.0 mg/mL

Further, the same measurement conditions of the weight-average molecular weight (Mw) and the number-average molecular weight (Mn) apply to the following Synthesis Examples 2 to 9.

### Synthesis Example 2

First, (3-ethyloxetan-3-yl)methylbicyclo[2.2.1]hepta-2-ene-5-carboxylic acid (8.26 g, 35 mmol), maleimide (2.67 g, 27.5 mmol), N-cyclohexylmaleimide (4.03 g, 22.5 mmol), norbornene carboxylic acid (0.65 g, 5 mmol), methyl glycidyl ether norbornene (0.9 g, 5 mmol), and dibutyl fumarate (1.14 g, 5 mmol) were weighed into a reaction container equipped with a stirrer and a cooler. Further, 10 g of propylene glycol monomethyl ether acetate in which V-601 (0.92 g, 4.0 mmol) was dissolved was added to the reaction container, and the mixture was stirred and dissolved. Next, after dissolved oxygen in the system was removed by nitrogen bubbling, the container was maintained at 70° C. in a nitrogen atmosphere and the mixture was allowed to react for 5 hours. Subsequently, the reaction mixture was cooled to room temperature, and 30 g of MEK was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 13.1 g and the yield rate thereof was 74%. Further, the weight-average molecular weight Mw of the polymer was 6,460 and the dispersity (weight-average molecular weight Mw/number-average molecular weight Mn) thereof was 1.92.

The obtained polymer has a structure represented by the above-described Formula (20).

### Synthesis Example 3

First, triethoxysilyl norbornene (3.84 g, 15 mmol), maleimide (2.43 g, 25 mmol), N-cyclohexylmaleimide (4.48 g, 25 mmol), norbornene carboxylic acid (3.25 g, 25 mmol), methyl glycidyl ether norbornene (0.9 g, 5 mmol), and dibutyl fumarate (1.14 g, 5 mmol) were weighed into a reaction container equipped with a stirrer and a cooler. Further, 9.1 g of propylene glycol monomethyl ether acetate in which V-601 (0.92 g, 4.0 mmol) was dissolved was added to the reaction container, and the mixture was stirred and dissolved. Next, after dissolved oxygen in the system was removed by nitrogen bubbling, the container was maintained at 70° C. in a nitrogen atmosphere and the mixture was allowed to react for 5 hours. Subsequently, the reaction mixture was cooled to room temperature, and 30 g of MEK was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 13.2 g and the yield rate thereof was 82%. Further, the weight-average molecular weight Mw of the polymer was 11,430 and the dispersity (weight-average molecular weight Mw/number-average molecular weight Mn) thereof was 2.34.

The obtained polymer has a structure represented by the following Formula (21).

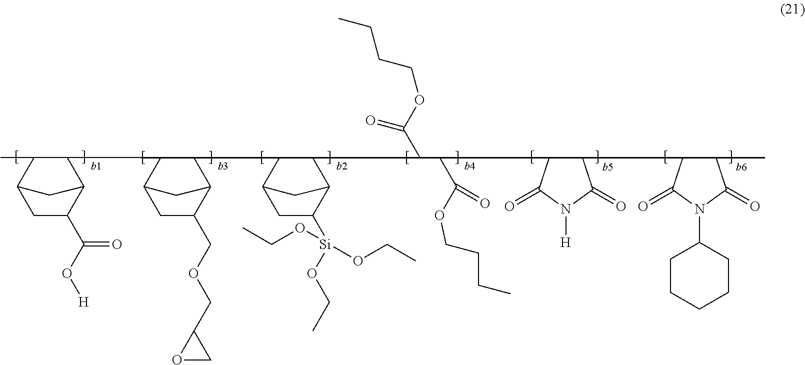

### Synthesis Example 4

First, (3-ethyloxetan-3-yl)methylbicyclo[2.2.1]hepta-2-ene-5-carboxylic acid) (6.66 g, 28.2 mmol), maleimide (2.74 g, 28.2 mmol), N-cyclohexylmaleimide (1.01 g, 5.6 mmol), butanediol vinyl glycidyl ether (4.45 g, 28.2 mmol), and dibutyl fumarate (5.15 g, 22.5 mmol) were weighed into a reaction container equipped with a stirrer and a cooler. Further, 19.5 g of propylene glycol monomethyl ether acetate in which V-601 (0.52 g, 2.3 mmol) was dissolved was added to the reaction container, and the mixture was stirred and dissolved. Next, after dissolved oxygen in the system was removed by nitrogen bubbling, the container was maintained at 50° C. in a nitrogen atmosphere and the mixture was allowed to react for 16 hours. Subsequently, the reaction mixture was cooled to room temperature, and 26.7 g of MEK was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 10.7 g and the yield rate thereof was 53%. Further, the weight-average molecular weight Mw of the polymer was 16,100 and the dispersity (weight-average molecular weight Mw/number-average molecular weight Mn) thereof was 2.73.

The obtained polymer has a structure represented by the following Formula (22).

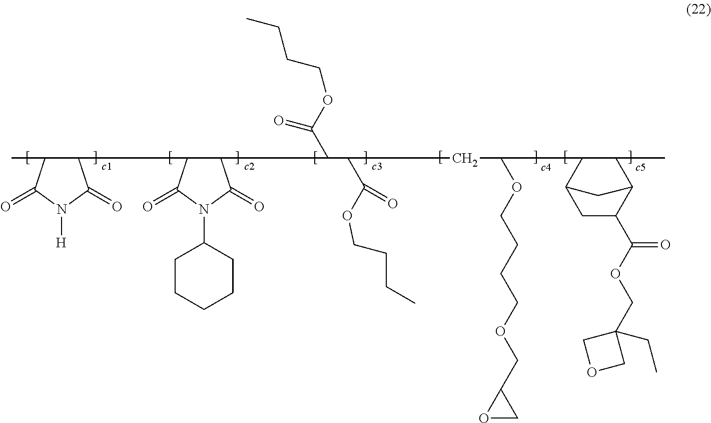 [SMILES: CCCCOC(=O)C(CC(OCCCCOCC1CO1)C1C2CC(C(=O)OCC3(CC)COC3)C(C2)C1C)C(C)(C(=O)OCCCC)C1C(=O)N(C2CCCCC2)C(=O)C1C1C(=O)NC(=O)C1C]

### Synthesis Example 5

First, (3-ethyloxetan-3-yl)methylbicyclo[2.2.1]hepta-2-ene-5-carboxylic acid) (1.18 g, 5 mmol), maleimide (2.43 g, 25 mmol), N-cyclohexylmaleimide (4.48 g, 25 mmol), norbornene carboxylic acid (3.58 g, 27.5 mmol), octyl methyl glycidyl ether norbornene (2.75 g, 12.5 mmol), and dibutyl fumarate (1.14 g, 5 mmol) were weighed into a reaction container equipped with a stirrer and a cooler. Further, 8.9 g of propylene glycol monomethyl ether acetate in which V-601 (0.92 g, 4.0 mmol) was dissolved was added to the reaction container, and the mixture was stirred and dissolved. Next, after dissolved oxygen in the system was removed by nitrogen bubbling, the container was maintained at 70° C. in a nitrogen atmosphere and the mixture was allowed to react for 5 hours. Subsequently, the reaction mixture was cooled to room temperature, and 30 g of MEK was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 12.7 g and the yield rate thereof was 81%. Further, the weight-average molecular weight Mw of the polymer was 10,880 and the dispersity (weight-average molecular weight Mw/number-average molecular weight Mn) thereof was 2.37.

The obtained polymer has a structure represented by the following Formula (23).

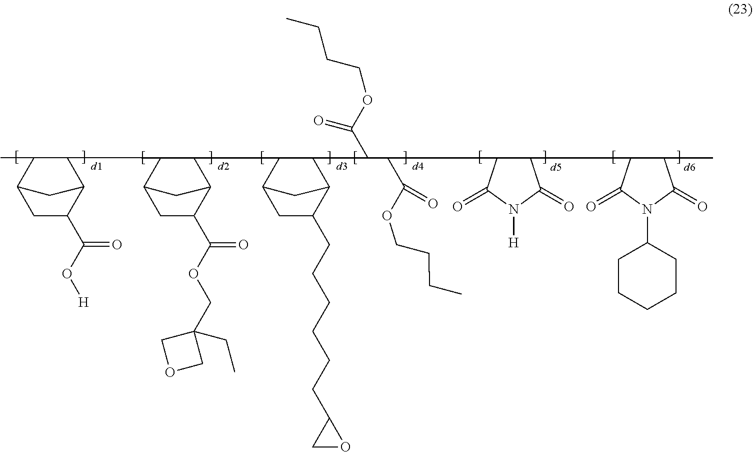

### Synthesis Example 6

First, triethoxysilyl norbornene (3.20 g, 12.5 mmol), maleimide (2.43 g, 25 mmol), N-cyclohexylmaleimide (4.48 g, 25 mmol), norbornene carboxylic acid (3.58 g, 27.5 mmol), octyl methyl glycidyl ether norbornene (1.10 g, 5 mmol), and dibutyl fumarate (1.14 g, 5 mmol) were weighed into a reaction container equipped with a stirrer and a cooler. Further, 8.9 g of propylene glycol monomethyl ether acetate in which V-601 (0.92 g, 4.0 mmol) was dissolved was added to the reaction container, and the mixture was stirred and dissolved. Next, after dissolved oxygen in the system was removed by nitrogen bubbling, the container was maintained at 70° C. in a nitrogen atmosphere and the mixture was allowed to react for 5 hours. Subsequently, the reaction mixture was cooled to room temperature, and 30 g of MEK was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 13.2 g and the yield rate thereof was 83%. Further, the weight-average molecular weight Mw of the polymer was 12,100 and the dispersity (weight-average molecular weight Mw/number-average molecular weight Mn) thereof was 2.40.

The obtained polymer has a structure represented by the following Formula (24).

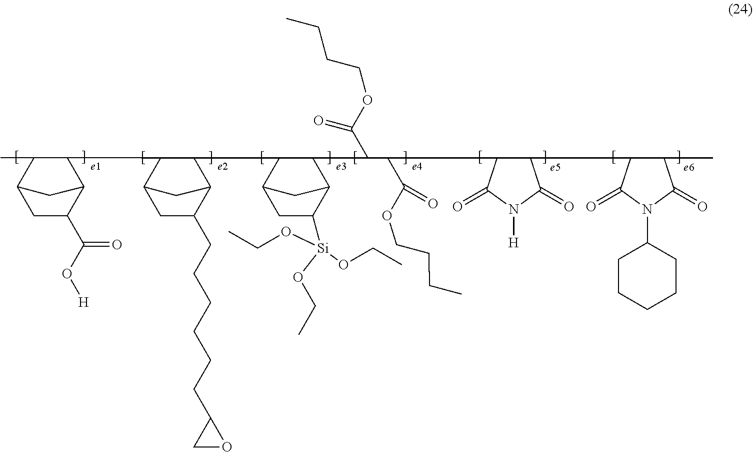

### Synthesis Example 7

First, maleimide (2.18 g, 22.5 mmol), N-cyclohexylmaleimide (4.92 g, 27.5 mmol), norbornene carboxylic acid (2.60 g, 20 mmol), (3-ethyloxetan-3-yl)methylbicyclo[2.2.1]hepta-2-ene-5-carboxylic acid (5.90 g, 25 mmol), and dibutyl fumarate (1.14 g, 5 mmol) were weighed into a reaction container equipped with a stirrer and a cooler. Further, 9.5 g of propylene glycol monomethyl ether acetate in which V-601 (0.92 g, 4.0 mmol) was dissolved was added to the reaction container, and the mixture was stirred and dissolved. Next, after dissolved oxygen in the system was removed by nitrogen bubbling, the container was maintained at 70° C. in a nitrogen atmosphere and the mixture was allowed to react for 5 hours. Subsequently, the reaction mixture was cooled to room temperature, and 30 g of MEK was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 13.8 g and the yield rate thereof was 82%. Further, the weight-average molecular weight Mw of the polymer was 7,120 and the dispersity (weight-average molecular weight Mw/number-average molecular weight Mn) thereof was 1.95.

The obtained polymer has a structure represented by the following Formula (25).

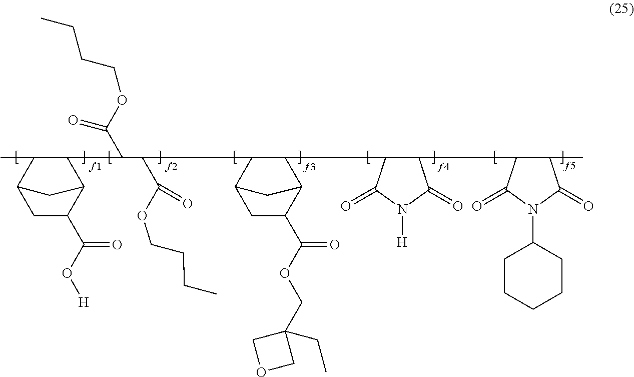 [SMILES: CCCCOC(=O)C(C1C2CC(C(=O)OCC3(CC)COC3)C(C2)C1CC1C(=O)NC(=O)C1C1C(=O)N(C2CCCCC2)C(=O)C1C)C(C)(C(=O)OCCCC)C1C(C)C2CC(C(=O)O)C1C2]

### Synthesis Example 8

First, maleimide (2.18 g, 22.5 mmol), N-cyclohexylmaleimide (4.92 g, 27.5 mmol), norbornene carboxylic acid (3.25 g, 25 mmol), (3-ethyloxetan-3-yl)methylbicyclo[2.2.1]hepta-2-ene-5-carboxylic acid (1.18 g, 5 mmol), dibutyl fumarate (1.14 g, 5 mmol), and methyl glycidyl ether norbornene (2.70 g, 15 mmol) were weighed into a reaction container equipped with a stirrer and a cooler. Further, 9.0 g of propylene glycol monomethyl ether acetate in which benzoyl peroxide (0.97 g, 4.0 mmol) was dissolved was added to the reaction container, and the mixture was stirred and dissolved. Next, after dissolved oxygen in the system was removed by nitrogen bubbling, the container was maintained at 70° C. in a nitrogen atmosphere and the mixture was allowed to react for 5 hours. Subsequently, the reaction mixture was cooled to room temperature, and 30 g of MEK was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 13.0 g and the yield rate thereof was 84%. Further, the weight-average molecular weight Mw of the polymer was 8,610 and the dispersity (weight-average molecular weight Mw/number-average molecular weight Mn) thereof was 2.06.

The obtained polymer has a structure represented by the above-described Formula (20).

### Synthesis Example 9

Methyl glycidyl ether norbornene (0.66 g, 3 mmol), hexafluoromethyl alcohol norbornene (7.40 g, 27 mmol), and toluene (18 g) were injected into a reaction container equipped with a stirrer, and the inside thereof was replaced with dry nitrogen gas. When the content was heated and the internal temperature reached 60° C., a solution obtained by dissolving (η⁶-toluene)Ni(C₆F₅)₂ (0.29 g, 0.60 mmol) in 10 g of toluene was added thereto. Next, after the solution was allowed to react at 60° C. for 5 hours, the solution was cooled to room temperature. 30 g of THF was added to the reacted solution, acetate (6 g) and 30% hydrogen peroxide water (8.0 g) were further added thereto, and then the solution was stirred at room temperature for 5 hours. Thereafter, a washing operation using ion exchange water was performed three times. An organic layer was concentrated using an evaporator and re-precipitated using 300 g of hexane, thereby obtaining a white solid. The obtained solid was dried overnight using a vacuum dryer at 30° C., and then 6.0 g of white powder was obtained. The Mw of the obtained polymer was 23, 500 and the Mn thereof was 13, 700 when measured by GPC.

The obtained polymer has a structure represented by the following Formula (26).

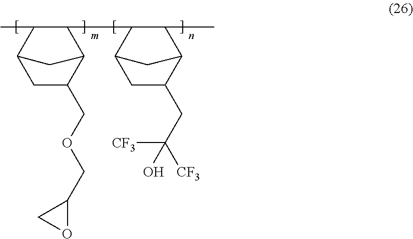

(Preparation of Photosensitive Resin Composition)

### Example 1

10.0 g of the polymer synthesized in Synthesis Example 1, 2.2 g of an esterification product (PA-28, manufactured by Daito Chemix Corporation) of 4,4′-(1-{4-[1(4-hydroxyphenyl)-1-methylethyl]phenyl}ethylidene)bisphenol and 1,2-naphthoquinonediazide-5-sulfonyl chloride, 3.0 g of s-caprolactone-modified 3,4′-epoxycyclohexylmethyl 3,4-epoxycyclohexanecarboxylate (CELLOXIDE 2081, manufactured by Daicel Corporation), 0.2 g of diphenyl[4-(phenylthio)phenyl]sulfonium tetrakis(pentafluorophenyl)borate (CPI-110B, manufactured by San-Apro Ltd.), 1.0 g of KBM-403 (manufactured by Shin-Etsu Chemical Co., Ltd.) for improving adhesion, and 0.05 g of F-557 (manufactured by DIC Corporation) for preventing radial striations occurring on a resist film at the time of spin-coating were dissolved in a mixed solvent of propylene glycol monomethyl ether acetate, diethylene glycol methyl ethyl ether, and benzyl alcohol at a mixing ratio of 50:42.5:7.5 such that the proportion of a solid content became 20%. This solution was filtered off using a PTFE filter having a pore size of 0.2 μm, thereby preparing a positive type photosensitive resin composition.

### Example 2

A positive type photosensitive resin composition was prepared in the same manner as in Example 1 except that the polymer synthesized in Synthesis Example 2 was used. Further, the blending amount of each component is listed in Table 1.

### Example 3

10.0 g of the polymer synthesized in Synthesis Example 3, 2.0 g of an esterification product (PA-28, manufactured by Daito Chemix Corporation) of 4,4′-(1-{4-[1(4-hydroxyphenyl)-1-methylethyl]phenyl}ethylidene)bisphenol and 1,2-naphthoquinonediazide-5-sulfonyl chloride, 2.0 g of ε-caprolactone-modified 3,4′-epoxycyclohexylmethyl 3,4-epoxycyclohexanecarboxylate (CELLOXIDE 2081, manufactured by Daicel Corporation), 0.5 g of diphenyl[4-(phenylthio)phenyl]sulfonium tetrakis(pentafluorophenyl)borate (CPI-110B, manufactured by San-Apro Ltd.), 0.5 g of KBM-403 (manufactured by Shin-Etsu Chemical Co., Ltd.) for improving adhesion, and 0.05 g of F-557 (manufactured by DIC Corporation) for preventing radial striations occurring on a resist film at the time of spin-coating were dissolved in a mixed solvent of propylene glycol monomethyl ether acetate and diethylene glycol methyl ethyl ether at a mixing ratio of 50:50 such that the proportion of a solid content became 20%. This solution was filtered off using a PTFE filter having a pore size of 0.2 μm, thereby preparing a positive type photosensitive resin composition.

### Example 4

10.0 g of the polymer synthesized in Synthesis Example 4, 2.0 g of an esterification product (PA-28, manufactured by Daito Chemix Corporation) of 4,4′-(1-{4-[1(4-hydroxyphenyl)-1-methylethyl]phenyl}ethylidene)bisphenol and 1,2-naphthoquinonediazide-5-sulfonyl chloride, 0.2 g of diphenyl[4-(phenylthio)phenyl]sulfonium tetrakis(pentafluorophenyl)borate (CPI-110B, manufactured by San-Apro Ltd.), 0.5 g of KBM-403 (manufactured by Shin-Etsu Chemical Co., Ltd.) for improving adhesion, and 0.05 g of F-557 (manufactured by DIC Corporation) for preventing radial striations occurring on a resist film at the time of spin-coating were dissolved in a mixed solvent of propylene glycol monomethyl ether acetate and diethylene glycol methyl ethyl ether at a mixing ratio of 70:30 such that the proportion of a solid content became 20%. This solution was filtered off using a PTFE filter having a pore size of 0.2 μm, thereby preparing a positive type photosensitive resin composition.

### Example 5

A positive type photosensitive resin composition was prepared in the same manner as in Example 1 except that the polymer synthesized in Synthesis Example 5 was used. Further, the blending amount of each component is listed in Table 1.

### Example 6

A positive type photosensitive resin composition was prepared in the same manner as in Example 1 except that the polymer synthesized in Synthesis Example 6 was used. Further, the blending amount of each component is listed in Table 1.

### Example 7

A positive type photosensitive resin composition was prepared in the same manner as in Example 1 except that the polymer synthesized in Synthesis Example 7 was used. Further, the blending amount of each component is listed in Table 1.

### Example 8

A positive type photosensitive resin composition was prepared in the same manner as in Example 1 except that the polymer synthesized in Synthesis Example 8 was used. Further, the blending amount of each component is listed in Table 1.

### Comparative Example 1

A positive type photosensitive resin composition was prepared in the same manner as in Example 1 except that the polymer synthesized in Synthesis Example 9 was used. Further, the blending amount of each component is listed in Table 1.

(Crack Resistance)

In Examples 1 to 8 and Comparative Example 1, the crack resistance was evaluated in the following manner. First, a Corning 1737 glass substrate having a length of 100 mm and a width of 100 mm (manufactured by Corning Incorporated) was spin-coated with the obtained photosensitive resin composition and baked at 100° C. for 120 seconds using a hot plate, thereby obtaining a thin film A having a thickness of approximately 3.5 μm. Next, the thin film was exposed to light using a mask having a hole pattern having a size of 5 μm with a g+h+i line mask aligner (PLA-501F, manufactured by Canon Inc.). A resist pattern was then formed by performing development using a developer under the conditions of 23° C. for 90 seconds. Moreover, the development treatment was respectively carried out using a 0.5 mass % tetramethylammonium hydroxide aqueous solution as the developer in Examples 1 and 3 to 8 and the development treatment was respectively carried out using a 2.38 mass % tetramethylammonium hydroxide aqueous solution as the developer in Example 2 and Comparative Example 1. Thereafter, the surface of the formed resist pattern was observed using an SEM. A case where the thin film was cracked was evaluated as “poor” and a case where the thick film was not cracked was evaluated as “good”.

(Reworkability)

Reworkability of the photosensitive resin composition for each of Examples 1 to 8 and Comparative Example 1 was evaluated in the following manner. First, a Corning 1737 glass substrate having a length of 100 mm and a width of 100 mm (manufactured by Corning Incorporated) was spin-coated (rotation speed of 500 rpm to 2500 rpm) with the obtained photosensitive resin composition and pre-baked at 100° C. for 120 seconds using a hot plate, thereby obtaining a resin film having a thickness of approximately 3.0 μm. Next, the resin film was exposed to light such that the amount of integrated light of g+h+i line became 300 mJ/cm² using a g+h+i line mask aligner (PLA-501F (ultra-high pressure mercury lamp), manufactured by Canon Inc.), thereby obtaining a mask with a mask pattern having a size of 5 μm. Next, the resin film was subjected to a development treatment using a developer and rinsed with pure water, thereby obtaining a thin film provided with a pattern. Moreover, the development treatment was respectively carried out using a 0.5 mass % tetramethylammonium hydroxide aqueous solution as the developer in Examples 1 and 3 to 8 and the development treatment was respectively carried out using a 2.38 mass % tetramethylammonium hydroxide aqueous solution as the developer in Example 2 and Comparative Example 1.

Next, this thin film provided with the obtained pattern was subjected to a bleach treatment without using a mask such that the amount of integrated light of g+h+i line became 300 mJ/cm². Subsequently, after the resin film was allowed to stand for 24 hours in a yellow room (using a HEPA filter) in which the temperature and the humidity were respectively maintained to 23±1° C. and 40±5%, the resin film was subjected to a bleach treatment again without using a mask such that the amount of integrated light of g+h+i line became 300 mJ/cm². Next, the resin film was immersed in a 2.38% tetramethylammonium hydroxide (TMAH) aqueous solution at a temperature of 23±1° C. for 120 seconds. At this time, the presence or absence of residues on the resin film of the substrate was observed using a microscope. The reworkability was evaluated as “poor” when residues of the resin film were observed and as “good” when residues of the resin film were not observed.

(Formation of Thin Film Pattern)

In Examples 1 to 8 and Comparative Example 1, a thin film pattern was formed in the following manner. First, a Corning 1737 glass substrate having a length of 100 mm and a width of 100 mm (manufactured by Corning Incorporated) was spin-coated (rotation speed of 300 rpm to 2500 rpm) with the obtained photosensitive resin composition and baked at 100° C. for 120 seconds using a hot plate, thereby obtaining a thin film A having a thickness of approximately 3.5 μm. Next, the thin film A was exposed to light at an optimum exposure amount such that the ratio of the line width to the space width of 5 μm was set to 1:1 using a g+h+i line mask aligner (PLA-501F, manufactured by Canon Inc.), and the resultant was developed at 23° C. for 90 seconds using a developer, thereby obtaining a thin film B provided with a pattern having a ratio of the line width to the space width of 1:1. Moreover, the development treatment was respectively carried out using a 0.5 mass % tetramethylammonium hydroxide aqueous solution as the developer in Examples 1 and 3 to 8 and the development treatment was respectively carried out using a 2.38 mass % tetramethylammonium hydroxide aqueous solution as the developer in Example 2 and Comparative Example 1. Subsequently, the entire surface of the thin film B was exposed to light using PLA-501F at 300 mJ/cm² and subjected to a post bake treatment by heating in an oven at 230° C. for 60 minutes, thereby obtaining a patterned thin film C having a thickness of approximately 3.0 μm.

(Evaluation of Residual Film Rate after Development and Post-Baking)

In Examples 1 to 8 and Comparative Example 1, the residual film rate was calculated using the following equations from the film thicknesses of the thin film A, the thin film B, and the thin film C obtained by forming the above-described thin film pattern.

Residual film rate after development (%)=[film thickness (μm) of thin film B/film thickness (μm) of thin film A]]×100

Residual film rate after post-baking (%)=[film thickness (μm) of thin film C/film thickness (μm) of thin film A]]×100

(Evaluation of Developability)

In Examples 1 to 8 and Comparative Example 1, the 5 μm-sized pattern of the thin film B obtained by forming the above-described thin film pattern was observed using a scanning electron microscope (SEM). The developability was evaluated as “poor” when residues were seen in a space portion and as “good” when residues were not seen in a space portion.

(Evaluation of Relative Dielectric Constant)

In Examples 1 to 8 and Comparative Example 1, a thin film having a thickness of 3.0 μm without a pattern was obtained on an aluminum substrate by performing the same operation as the operation for forming the above-described thin film pattern except that a test pattern was not exposed to light or developed using PLA-501F and an aluminum substrate was used as a substrate. Thereafter, a gold electrode was formed on this thin film and the relative dielectric constant of the electrostatic capacity obtained using an LCR meter (4282A, manufactured by Hewlett-Packard Company) was calculated under the conditions of room temperature (25° C.) and 10 kHz.

(Evaluation of Transmittance)

In Examples 1 to 8 and Comparative Example 1, a thin film without a pattern was obtained on a glass substrate by performing the same operation as the operation for forming the above-described thin film pattern except that a test pattern was not exposed to light. Further, the light transmittance (%) of the thin film at a wavelength of 400 nm was measured using an ultraviolet-visible light spectrophotometer, and the numerical value converted into transmittance for a film thickness of 3 μm was set to the transmittance.

(Evaluation of Liquid Chemical Resistance)

In Examples 1 to 8 and Comparative Example 1, the swelling rate and the recovery rate were measured in the following manner. First, a Corning 1737 glass substrate having a length of 100 mm and a width of 100 mm (manufactured by Corning Incorporated) was spin-coated with the obtained photosensitive resin composition and pre-baked at 100° C. for 120 seconds using a hot plate, thereby obtaining a resin film having a thickness of approximately 3.5 μm. Next, the resin film was immersed in a developer for 90 seconds, and then rinsed with pure water. Moreover, the development treatment was respectively carried out using a 0.5 mass % tetramethylammonium hydroxide aqueous solution as the developer in Examples 1 and 3 to 8 and the development treatment was respectively carried out using a 2.38 mass % tetramethylammonium hydroxide aqueous solution as the developer in Example 2 and Comparative Example 1. The entire surface of the resin film was then exposed to light such that the amount of integrated light of g+h+i line became 300 mJ/cm² using a g+h+i line mask aligner (PLA-501F (ultra-high pressure mercury lamp), manufactured by Canon Inc.). Thereafter, the resin film was subjected to a thermosetting treatment in an oven at 230° C. for 60 minutes. Subsequently, the film thickness of the obtained cured film (first film thickness) was measured. Further, the cured film was immersed in TOK106 (manufactured by TOKYO OHKA KOGYO CO., LTD.) at 70° C. for 15 minutes, and then rinsed with pure water for 30 seconds. At this time, the film thickness obtained after the curing film was rinsed was set to a second film thickness and the swelling rate was calculated from the following expression.

Swelling rate: [(second film thickness−first film thickness)/(first film thickness)]×100(%)

Next, the cured film was heated in an oven at 230° C. for 15 minutes and the film thickness after heating (third film thickness) was measured. Further, the recovery rate was calculated from the following expression.

Recovery rate: [(third film thickness)/(first film thickness)]×100(%)

(Sensitivity)

In Examples 1 to 8 and Comparative Example 1, the sensitivity was measured in the following manner. First, a Corning 1737 glass substrate having a length of 100 mm and a width of 100 mm (manufactured by Corning Incorporated) was spin-coated with the obtained photosensitive resin composition and baked at 100° C. for 120 seconds using a hot plate, thereby obtaining a thin film A having a thickness of approximately 3.5 μm. Next, the thin film A was exposed to light using a mask having a hole pattern having a size of 5 μm with a g+h+i line mask aligner (PLA-501F, manufactured by Canon Inc.). A resist pattern was then formed by performing development using a developer under the conditions of 23° C. for 90 seconds. Moreover, the development treatment was respectively carried out using a 0.5 mass % tetramethylammonium hydroxide aqueous solution as the developer in Examples 1 and 3 to 8 and the development treatment was respectively carried out using a 2.38 mass % tetramethylammonium hydroxide aqueous solution as the developer in Example 2 and Comparative Example 1. Thereafter, the formed resist pattern was observed using an SEM and the exposure amount (mJ/cm²), at which a hole pattern having a size of 5 μm² was obtained, is set to the sensitivity.

TABLE 1

| | | | Example 1 | Example 2 | Example 3 | Example 4 | Example 5 |
|---|---|---|---|---|---|---|---|
| Positive | Polymer | Synthesis | 10.0 (60.8) | | | | |
| photosensitive | | Example 1 | | | | | |
| resin | | Synthesis | | 10.0 (64.3) | | | |
| composition | | Example 2 | | | | | |
| | | Synthesis | | | 10.0 (66.5) | | |
| | | Example 3 | | | | | |
| | | Synthesis | | | | 10.0 (78.4) | |
| | | Example 4 | | | | | |
| | | Synthesis | | | | | 10.0 (65.6) |
| | | Example 5 | | | | | |
| | | Synthesis | | | | | |
| | | Example 6 | | | | | |
| | | Synthesis | | | | | |
| | | Example 7 | | | | | |
| | | Synthesis | | | | | |
| | | Example 8 | | | | | |
| | | Synthesis | | | | | |
| | | Example 9 | | | | | |

| | | | | | |
|---|---|---|---|---|---|
| PA-28 | 2.2 (13.4) | 2.0 (12.9) | 2.0 (13.3) | 2.0 (15.7) | 2.0 (13.1) |
| CELLOXIDE 2081 | 3.0 (18.2) | 2.0 (12.9) | 2.0 (13.3) | | 2.0 (13.1) |
| CPI-110B | 0.2 (1.2) | 0.5 (3.2) | 0.5 (3.3) | 0.2 (1.6) | 0.2 (1.3) |
| KBM-403 | 1.0 (6.1) | 1.0 (6.4) | 0.5 (3.3) | 0.5 (3.9) | 1.0 (6.6) |
| F-557 | 0.05 (0.3) | 0.05 (0.3) | 0.05 (0.3) | 0.05 (0.4) | 0.05 (0.3) |

| | | | | | |
|---|---|---|---|---|---|
| Crack resistance | Good | Good | Good | Good | Good |
| Reworkability | Good | Good | Good | Good | Good |
| Residual film rate after | 92 | 90 | 91 | 85 | 82 |
| development (%) | | | | | |
| Residual film rate after | 88 | 86 | 86 | 80 | 73 |
| post-baking (%) | | | | | |
| Developability | Good | Good | Good | Good | Good |
| Relative dielectric constant | 3.5 | 3.6 | 3.4 | 3.4 | 3.2 |
| Transmittance (%) | 93 | 93 | 88 | 83 | 89 |
| Swelling rate (%) | 5 | 6 | 3 | 5 | 0 |
| Recovery rate (%) | 100 | 100 | 97 | 102 | 98 |
| Sensitivity (mJ/cm²) | 320 | 300 | 320 | 350 | 380 |

| | | | | | | Comparative |
|---|---|---|---|---|---|---|
| | | | Example 6 | Example 7 | Example 8 | Example 1 |
| Positive | Polymer | Synthesis | | | | |
| photosensitive | | Example 1 | | | | |
| resin | | Synthesis | | | | |
| composition | | Example 2 | | | | |
| | | Synthesis | | | | |
| | | Example 3 | | | | |
| | | Synthesis | | | | |
| | | Example 4 | | | | |
| | | Synthesis | | | | |
| | | Example 5 | | | | |
| | | Synthesis | 10.0 (65.6) | | | |
| | | Example 6 | | | | |
| | | Synthesis | | 10.0 (66.5) | | |
| | | Example 7 | | | | |
| | | Synthesis | | | 10.0 (60.8) | |
| | | Example 8 | | | | |
| | | Synthesis | | | | 10.0 (65.6) |
| | | Example 9 | | | | |

| | | | | |
|---|---|---|---|---|
| PA-28 | 2.0 (13.1) | 2.0 (13.3) | 2.2 (13.4) | 2.0 (13.1) |
| CELLOXIDE 2081 | 2.0 (13.1) | 2.0 (13.3) | 3.0 (18.2) | 2.0 (13.1) |
| CPI-110B | 0.2 (1.3) | 0.5 (3.3) | 0.2 (1.2) | 0.2 (1.3) |
| KBM-403 | 1.0 (6.6) | 0.5 (3.3) | 1.0 (6.1) | 1.0 (6.6) |
| F-557 | 0.05 (0.3) | 0.05 (0.3) | 0.05 (0.3) | 0.05 (0.3) |

| | | | | |
|---|---|---|---|---|
| Crack resistance | Good | Good | Good | Poor |
| Reworkability | Good | Good | Good | Poor |
| Residual film rate after | 95 | 97 | 97 | 95 |
| development (%) | | | | |
| Residual film rate after | 82 | 88 | 84 | 91 |
| post-baking (%) | | | | |
| Developability | Good | Good | Good | Good |
| Relative dielectric constant | 3.3 | 3.4 | 3.4 | 4.5 |
| Transmittance (%) | 91 | 91 | 94 | 92 |
| Swelling rate (%) | 4 | 4 | 2 | 15 |
| Recovery rate (%) | 97 | 100 | 101 | 95 |
| Sensitivity (mJ/cm²) | 380 | 350 | 320 | 500 |

In Table 1, in the numerical values showing blending amounts of respective components included in the photosensitive resin composition, numerical values next to the parentheses represent the mass (g) of each component and numerical values inside the parentheses represent the blending ratio (% by mass) of each component based on 100% by mass of the total solid content of the resin composition (that is, the content of the components excluding the solvent).

(Undercut Resistance)

In Examples 3, 6 and Comparative Example 1, the undercut resistance was measured in the following manner. First, a Corning 1737 glass substrate having a length of 100 mm and a width of 100 mm (manufactured by Corning Incorporated) was spin-coated with the obtained photosensitive resin composition and baked at 100° C. for 120 seconds using a hot plate, thereby obtaining a thin film A having a thickness of approximately 3.5 μm. Next, the thin film was exposed to light using a mask having a hole pattern having a size of 5 μm with a g+h+i line mask aligner (PLA-501F, manufactured by Canon Inc.). A thin film provided with a pattern was then obtained by performing development using a developer under the conditions of 23° C. for 90 seconds. Moreover, the development treatment was respectively carried out using a 0.5 mass % tetramethylammonium hydroxide aqueous solution as the developer in Examples 3 and 6 and the development treatment was respectively carried out using a 2.38 mass % tetramethylammonium hydroxide aqueous solution as the developer in Comparative Example 1. Next, the entire surface of the obtained thin film provided with a pattern was exposed to light using PLA-501F at 300 mJ/cm² and subjected to a post bake treatment by heating in an oven at 230° C. for 60 minutes. Subsequently, the surface of the hole pattern formed on the thin film was observed using an SEM. In Examples 3 and 6, no undercut was observed at the lower end of the hole pattern. Meanwhile, in Comparative Example 1, an undercut was observed at the lower end of the hole pattern.

### Example 9

10.0 g of the polymer synthesized in Synthesis Example 1, 3.0 g of CELLOXIDE 2081 (manufactured by Daicel Corporation), 0.5 g of diphenyl[4-(phenylthio)phenyl]sulfonium tetrakis(pentafluorophenyl)borate (CPT-110B, manufactured by San-Apro Ltd.), 1.0 g of KBM-403 (manufactured by Shin-Etsu Chemical Co., Ltd.) for improving adhesion, and 0.05 g of F-557 (manufactured by DIC Corporation) for preventing radial striations occurring on a resist film at the time of spin-coating were dissolved in a mixed solvent of propylene glycol monomethyl ether acetate, diethylene glycol methyl ethyl ether, and benzyl alcohol at a mixing ratio of 42.5:50:7.5 such that the proportion of a solid content became 20%. This solution was filtered off using a PTFE filter having a pore size of 0.2 μm, thereby preparing a negative type photosensitive resin composition.

### Example 10

10.0 g of the polymer synthesized in Synthesis Example 1, 3.0 g of LX-01 (manufactured by Daicel Corporation), 0.5 g of diphenyl[4-(phenylthio)phenyl]sulfonium tetrakis(pentafluorophenyl)borate (CPI-110B, manufactured by San-Apro Ltd.), 1.0 g of KBM-403 (manufactured by Shin-Etsu Chemical Co., Ltd.) for improving adhesion, and 0.05 g of F-557 (manufactured by DIC Corporation) for preventing radial striations occurring on a resist film at the time of spin-coating were dissolved in a mixed solvent of propylene glycol monomethyl ether acetate, diethylene glycol methyl ethyl ether, and benzyl alcohol at a mixing ratio of 42.5:50:7.5 such that the proportion of a solid content became 20%. This solution was filtered off using a PTFE filter having a pore size of 0.2 μm, thereby preparing a negative type photosensitive resin composition.

### Example 11

A negative type photosensitive resin composition was prepared in the same manner as in Example 9 except that the polymer synthesized in Synthesis Example 3 was used. Further, the blending amount of each component is listed in Table 2.

### Example 12

A negative type photosensitive resin composition was prepared in the same manner as in Example 9 except that the polymer synthesized in Synthesis Example 6 was used. Further, the blending amount of each component is listed in Table 2.

(Crack Resistance)

In Examples 9 to 12, the crack resistance was evaluated in the following manner. First, a Corning 1737 glass substrate having a length of 100 mm and a width of 100 mm (manufactured by Corning Incorporated) was spin-coated with the obtained photosensitive resin composition and baked at 100° C. for 120 seconds using a hot plate, thereby obtaining a thin film A having a thickness of approximately 3.5 μm. Next, the thin film was exposed to light using a mask having a hole pattern having a size of 10 μm with a g+h+i line mask aligner (PLA-501F, manufactured by Canon Inc.). Then, the thin film was baked on a hot plate under the conditions of 120° C. for 120 seconds in Examples 9 and 10 and the conditions of 140° C. for 120 seconds in Examples 11 and 12. Next, a resist pattern was formed by performing development using a 0.5 mass % tetramethylammonium hydroxide aqueous solution under the conditions of 23° C. for 90 seconds. Subsequently, the surface of the formed resist pattern was observed using an SEM. A case where the thin film was cracked was evaluated as “poor” and a case where the thick film was not cracked was evaluated as “good”.

(Formation of Thin Film Pattern)

In Examples 9 to 12, a thin film pattern was formed in the following manner. First, a Corning 1737 glass substrate having a length of 100 mm and a width of 100 mm (manufactured by Corning Incorporated) was spin-coated (rotation speed of 300 rpm to 2500 rpm) with the obtained photosensitive resin composition and baked at 100° C. for 120 seconds using a hot plate, thereby obtaining a thin film A having a thickness of approximately 3.5 μm. The thin film A was then exposed to light at an optimum exposure amount such that the ratio of the line width to the space width of 10 μm was set to 1:1 using a g+h+i line mask aligner (PLA-501F, manufactured by Canon Inc.). Next, the thin film A was baked on a hot plate under the conditions of 120° C. for 120 seconds in Examples 9 and 10 and the conditions of 140° C. for 120 seconds in Examples 11 and 12. Thereafter, the thin film A was developed at 23° C. for 90 seconds using 0.5 mass % tetramethylammonium hydroxide aqueous solution, thereby obtaining a thin film B provided with a line and space pattern having a ratio of the line width to the space width of 1:1. Subsequently, the entire surface of the thin film B was exposed to light using PLA-501F at 300 mJ/cm² and subjected to a post bake treatment by heating in an oven at 230° C. for 60 minutes, thereby obtaining a patterned thin film C having a thickness of approximately 3.0 μm.

(Evaluation of Residual Film Rate after Development and after Post-Baking)

In Examples 9 to 12, the residual film rate was calculated using the following equations from the film thicknesses of the thin film A, the thin film B, and the thin film C obtained by forming the above-described thin film pattern.

Residual film rate after development (%)=[film thickness (μm) of thin film B/film thickness (μm) of thin film A]]×100

Residual film rate after post-baking (%)=[film thickness (μm) of thin film C/film thickness (μm) of thin film A]]×100

(Evaluation of Developability)

In Examples 9 to 12, the 10 μm-sized pattern of the thin film B obtained by forming the above-described thin film pattern was observed using a scanning electron microscope (SEM). The developability was evaluated by evaluating a case where residues were seen in a space portion as “poor” and a case where residues were not seen in a space portion as “good”.

(Evaluation of Relative Dielectric Constant)

In Examples 9 to 12, the relative dielectric constant was measured in the following manner. First, an aluminum substrate was spin-coated (rotation speed of 300 rpm to 2500 rpm) with the obtained photosensitive resin composition and baked at 100° C. for 120 seconds using a hot plate, thereby obtaining a thin film A having a thickness of approximately 3.5 μm. Next, the entire surface of the thin film was exposed to light using a g+h+i line mask aligner (PLA-501F, manufactured by Canon Inc.) at 300 mJ/cm². Next, the thin film after exposure to light was baked on a hot plate under the conditions of 120° C. for 120 seconds in Examples 9 and 10 and the conditions of 140° C. for 120 seconds in Examples 11 and 12. Next, the thin film was subjected to a post bake treatment by heating in an oven at 230° C. for 60 minutes, and then a thin film having a thickness of 3.0 μm without a pattern was obtained on the aluminum substrate. Thereafter, a gold electrode was formed on this thin film and the relative dielectric constant of the electrostatic capacity obtained using an LCR meter (4282A, manufactured by Hewlett-Packard Company) was calculated under the conditions of room temperature (25° C.) and 10 kHz.

(Evaluation of Transmittance)

In Examples 9 to 12, the transmittance was measured in the following manner. First, a Corning 1737 glass substrate having a length of 100 mm and a width of 100 mm (manufactured by Corning Incorporated) was spin-coated (rotation speed of 300 rpm to 2500 rpm) with the obtained photosensitive resin composition and baked at 100° C. for 120 seconds using a hot plate, thereby obtaining a thin film A having a thickness of approximately 3.5 μm. Next, the entire surface of the thin film was exposed to light using a g+h+i line mask aligner (PLA-501F, manufactured by Canon Inc.) at 300 mJ/cm². The thin film after exposure to light was then baked on a hot plate under the conditions of 120° C. for 120 seconds in Examples 9 and 10 and the conditions of 140° C. for 120 seconds in Examples 11 and 12. Thereafter, the thin film was developed at 23° C. for 90 seconds using 0.5 mass % tetramethylammonium hydroxide aqueous solution and then rinsed with pure water. Next, the thin film was subjected to a post bake treatment by heating in an oven at 230° C. for 60 minutes, thereby obtaining a thin film without a pattern on a glass substrate. The light transmittance (%) of the thin film at a wavelength of 400 nm was measured using an ultraviolet-visible light spectrophotometer, and the numerical value converted into transmittance for a film thickness of 3 μm was set to the transmittance.

(Evaluation of Liquid Chemical Resistance)

In Examples 9 to 12, the swelling rate and the recovery rate were measured in the following manner. First, a Corning 1737 glass substrate having a length of 100 mm and a width of 100 mm (manufactured by Corning Incorporated) was spin-coated with the obtained photosensitive resin composition and pre-baked at 100° C. for 120 seconds using a hot plate, thereby obtaining a resin film having a thickness of approximately 3.5 μm. Next, the entire surface of the resin film was exposed to light using a g+h+i line mask aligner (PLA-501F, manufactured by Canon Inc.) at 300 mJ/cm². The resin film after exposure to light was then baked under the conditions of 120° C. for 120 seconds in Examples 9 and 10 and the conditions of 140° C. for 120 seconds in Examples 11 and 12. Next, the resin film was immersed in a developer (0.5 wt % TMAH) for 90 seconds, and then rinsed with pure water. Next, the resin film was subjected to a thermosetting treatment in an oven at 230° C. for 60 minutes. Subsequently, the film thickness of the obtained cured film (first film thickness) was measured. Subsequently, the cured film was immersed in TOK106 (manufactured by TOKYO OHKA KOGYO CO., LTD.) at 70° C. for 15 minutes, and then rinsed with pure water for 30 seconds. At this time, the film thickness, obtained after the curing film was rinsed, was set to a second film thickness and the swelling rate was calculated from the following expression.

Swelling rate: [(second film thickness−first film thickness)/(first film thickness)]×100(%)

Next, the cured film was heated in an oven at 230° C. for 15 minutes and the film thickness after heating (third film thickness) was measured. Further, the recovery rate was calculated from the following expression.

Recovery rate: [(third film thickness)/(first film thickness)]×100(%)

(Sensitivity)

In Examples 9 to 12, the sensitivity was measured in the following manner. First, a Corning 1737 glass substrate having a length of 100 mm and a width of 100 mm (manufactured by Corning Incorporated) was spin-coated with the obtained photosensitive resin composition and baked at 100° C. for 120 seconds using a hot plate, thereby obtaining a thin film A having a thickness of approximately 3.5 μm. The thin film A was exposed to light by changing the exposure amount by 20 mJ/cm² each time using a g+h+i line mask aligner (PLA-501F, manufactured by Canon Inc.). Next, the thin film was baked on a hot plate under the conditions of 120° C. for 120 seconds in Examples 9 and 10 and the conditions of 140° C. for 120 seconds in Examples 11 and 12, and the film was developed using a 0.5 mass % tetramethylammonium hydroxide aqueous solution under the conditions of 23° C. for 90 seconds and rinsed with pure water, thereby obtaining a thin film B. In addition, the exposure amount satisfying “thin film B/thin film A×100-95%” was set to the sensitivity (mJ/cm²).

TABLE 2

| | | | Example 9 | Example 10 | Example 11 | Example 12 |
|---|---|---|---|---|---|---|
| Negative | Polymer | Synthesis Example 1 | 10.0 (68.7) | 10.0 (68.7) | | |
| photosensitive | | Synthesis Example 2 | | | | |
| resin | | Synthesis Example 3 | | | 10.0 (76.6) | |
| composition | | Synthesis Example 4 | | | | |
| | | Synthesis Example 5 | | | | |
| | | Synthesis Example 6 | | | | 10.0 (73.8) |
| | | Synthesis Example 7 | | | | |
| | | Synthesis Example 8 | | | | |
| | | Synthesis Example 9 | | | | |

| | | | | |
|---|---|---|---|---|
| PA-28 | | | | |
| CELLOXIDE 2081 | 3.0 (20.6) | | 2.0 (15.3) | 2.0 (14.8) |
| LX-01 | | 3.0 (20.6) | | |
| CPI-110B | 0.5 (3.4) | 0.5 (3.4) | 0.5 (3.8) | 0.5 (3.7) |
| KBM-403 | 1.0 (6.9) | 1.0 (6.9) | 0.5 (3.8) | 1.0 (7.4) |
| F-557 | 0.05 (0.3) | 0.05 (0.3) | 0.05 (0.4) | 0.05 (0.4) |

| | | | | |
|---|---|---|---|---|
| Crack resistance | Good | Good | Good | Good |
| Residual film rate after development (%) | 90 | 97 | 83 | 81 |
| Residual film rate after post-baking (%) | 94 | 92 | 91 | 90 |
| Developability | Good | Good | Good | Good |
| Relative dielectric constant | 3.49 | 3.37 | 3.44 | 3.45 |
| Transmittance (%) | 97 | 98 | 98 | 98 |
| Swelling rate (%) | 2 | 1 | 0 | 1 |
| Recovery rate (%) | 98 | 100 | 97 | 96 |
| Sensitivity (mJ/cm²) | 240 | 300 | 420 | 240 |

In Table 2, of the numerical values showing blending amounts of respective components included in the photosensitive resin composition, the numerical values next to the parentheses represent the mass (g) of each component and the numerical values inside the parentheses represent the blending ratio (% by mass) of each component based on 100% by mass of the total solid content of the resin composition (that is, the content of the components excluding the solvent).

(Undercut Resistance)

In Examples 11 and 12, the undercut resistance was measured in the following manner. First, a Corning 1737 glass substrate having a length of 100 mm and a width of 100 mm (manufactured by Corning Incorporated) was spin-coated with the obtained photosensitive resin composition and baked at 100° C. for 120 seconds using a hot plate, thereby obtaining a thin film A having a thickness of approximately 3.5 μm. Next, the thin film was exposed to light using a mask having a hole pattern having a size of 10 μm with a g+h+i line mask aligner (PLA-501F, manufactured by Canon Inc.). Next, the thin film was baked on a hot plate at 140° C. for 120 seconds. Subsequently, a thin film provided with a pattern was obtained by performing development using a 0.5 mass % tetramethylammonium hydroxide aqueous solution under the conditions of 23° C. for 90 seconds. Next, the entire surface of the obtained thin film provided with a pattern was exposed to light using PLA-501F at 300 mJ/cm² and subjected to a post bake treatment by heating in an oven at 230° C. for 60 minutes. Subsequently, the cross-section of the hole pattern formed on the thin film was observed using an SEM. In Examples 11 and 12, no undercut was observed at the lower end of the hole pattern.

This application claims priority based on Japanese Patent application No. 2014-058132, filed on Mar. 20, 2014, the entire disclosure of which is incorporated herein.

1. A polymer comprising:
a structural unit represented by the following Formula (1a); and
a structural unit represented by the following Formula (1b): 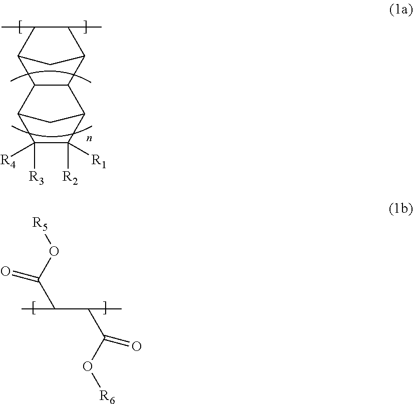
wherein in Formula (1a), n represents 0, 1, or 2, and R₁, R₂, R₃, and R₄ each independently represent hydrogen or an organic group having 1 to 10 carbon atoms, at least one of R₁, R₂, R₃, and R₄ representing an organic group including a carboxyl group, an epoxy ring, or an oxetane ring, and in Formula (1b), R₅ and R₆ each independently represent an alkyl group having 1 to 10 carbon atoms.

2. The polymer according to claim 1, further comprising a structural unit represented by the following Formula (2): 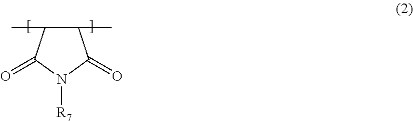
wherein in Formula (2), R₇ represents hydrogen or an organic group having 1 to 12 carbon atoms.

3. The polymer according to claim 1,
wherein at least one of R₁, R₂, R₃, and R₄ represents an organic group represented by the following Formula (3) in at least some structural units represented by the above-described Formula (1a): 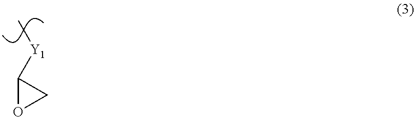
Y₁ in Formula (3) representing a divalent organic group having 4 to 8 carbon atoms.

4. The polymer according to claim 1, further comprising:
a structural unit represented by the following Formula (4): 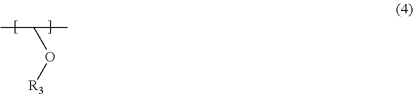
wherein in Formula (4), R₈ represents an organic group having 1 to 10 carbon atoms.

5. A photosensitive resin composition which is used for forming a permanent film, the composition comprising: the polymer according to claim 1.

6. The photosensitive resin composition according to claim 5 which is a positive type photosensitive resin composition.

7. The photosensitive resin composition according to claim 5 which is a negative type photosensitive resin composition.

8. An electronic device comprising: a permanent film formed from the photosensitive resin composition according to claim 5.
